(19) United States
(12) Patent Application Publication
(10) Pub. No.: US 2025/0107198 A1
(43) Pub. Date: Mar. 27, 2025

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/473,185

(22) Filed: Sep. 22, 2023

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 64/018; H10D 64/021; H10D 84/013; H10D 84/0135; H10D 84/0147; H10D 84/0149; H10D 84/038; H10D 84/83

(57) ABSTRACT

A method includes forming first, second, third, and fourth semiconductive sheets over a substrate and arranged in a vertical direction; forming a first source/drain region between the first and second semiconductive sheets, and a second source/drain region between the third and fourth semiconductive sheets; forming a first gate around each of the first semiconductive sheets, a second gate around each of the second semiconductive sheets, a third gate around each of the third semiconductive sheets, and a fourth gate around each of the fourth semiconductive sheets, wherein the second gate pitch of the third and fourth gates is greater than the first gate pitch of the first and second gates; forming first spacers interleaving with the first semiconductive sheets, and second spacers interleaving with the third semiconductive sheets, wherein the second lateral dimension of the second spacers is greater than the first lateral dimension of the first spacers.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a layout diagram of logic circuits of a semiconductor structure according to some embodiments of the present disclosure.

FIGS. 2A-2D, 2G, and 2H illustrate cross-sectional views obtained from reference cross-sections A-A′, B-B′, C-C′, D-D′, E-E′, F-F′ in FIG. 1.

FIGS. 2E and 2F illustrate cross-sectional views of a semiconductor structure corresponding to FIGS. 2C and 2D, respectively, according to some embodiments of the present disclosure.

FIGS. 3A-17B illustrate cross-sectional views of intermediate stages in the formation of a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

Reducing the vertical distance between the channel sheets in the GAA device can minimize source/drain resistance and capacitance. This compaction demands a more a thinner gate dielectric, which in turn complicates the formation of core devices, which benefit from a thinner gate dielectric for gate length scaling and performance, and I/O devices, which necessitate a thicker gate dielectric for high-voltage operations. Therefore, the development of device structures need to address both high-density/performance and high-voltage requirements. Therefore, the present disclosure provides a single chip integrating multiple device structures to achieve high density, high-speed, and high-voltage applications. Variations in gate pitches can serve distinct feature: a semiconductor device with its larger gate pitch, can employ a thicker inner spacer, reducing contact-to-gate capacitance; while another semiconductor device, with a smaller gate pitch, can employ a thinner inner spacer to preserve contact area and enhance density. For high-voltage devices, a thicker inner spacer can be utilized to improve the breakdown voltage between the gate and source/drain region. This design versatility grants designers greater latitude in optimizing chip density and performance.

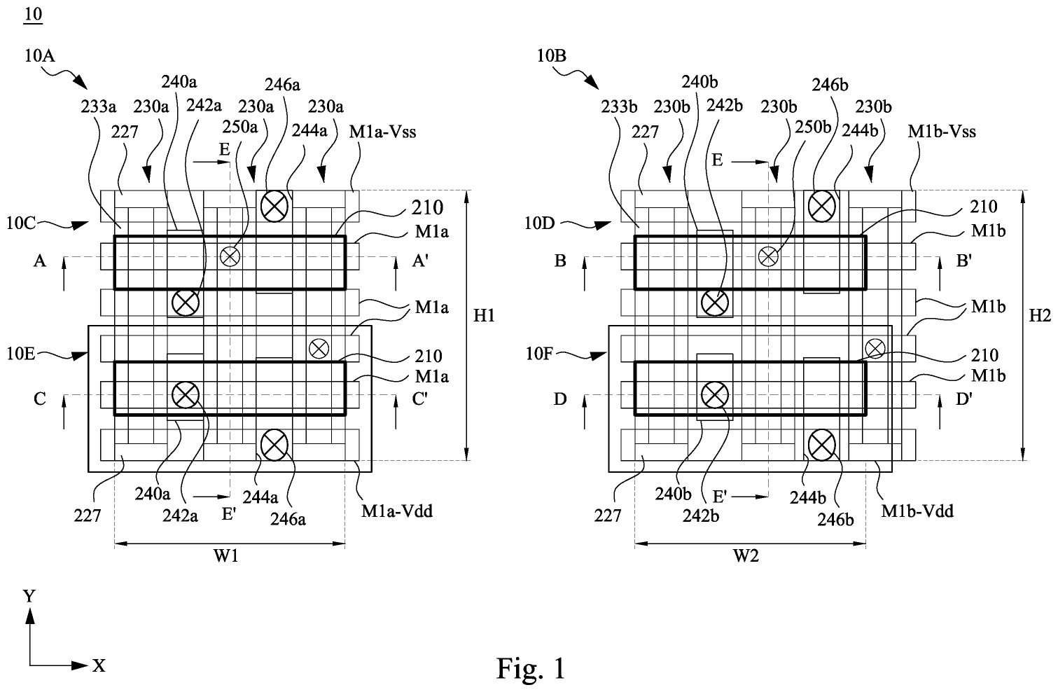

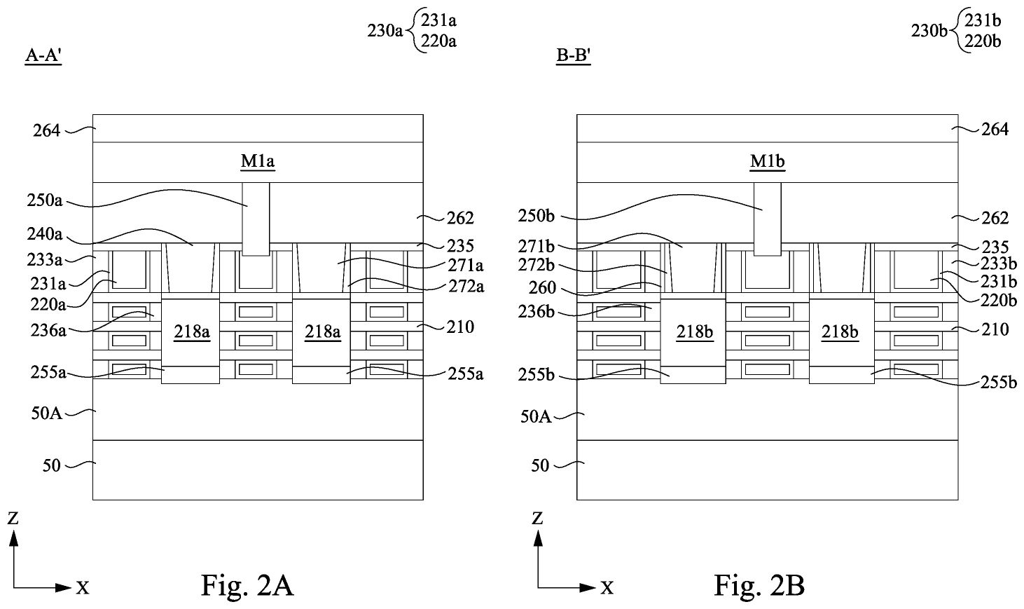

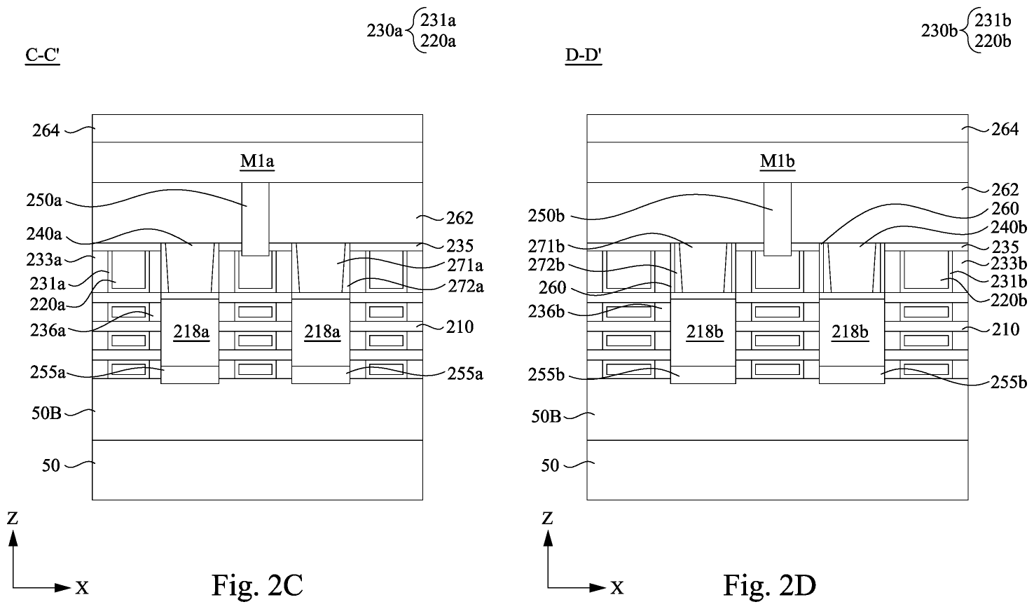

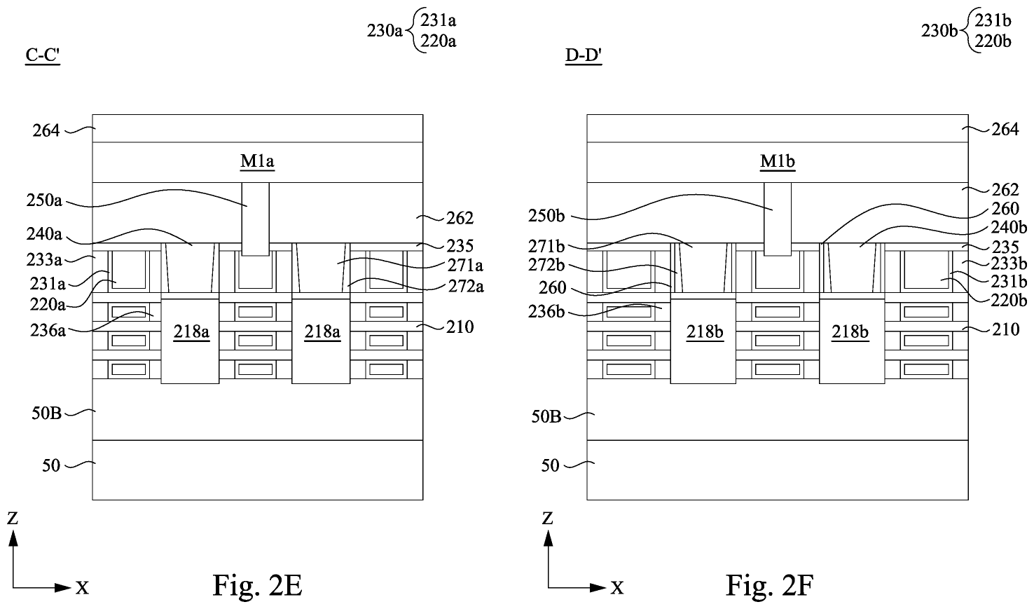

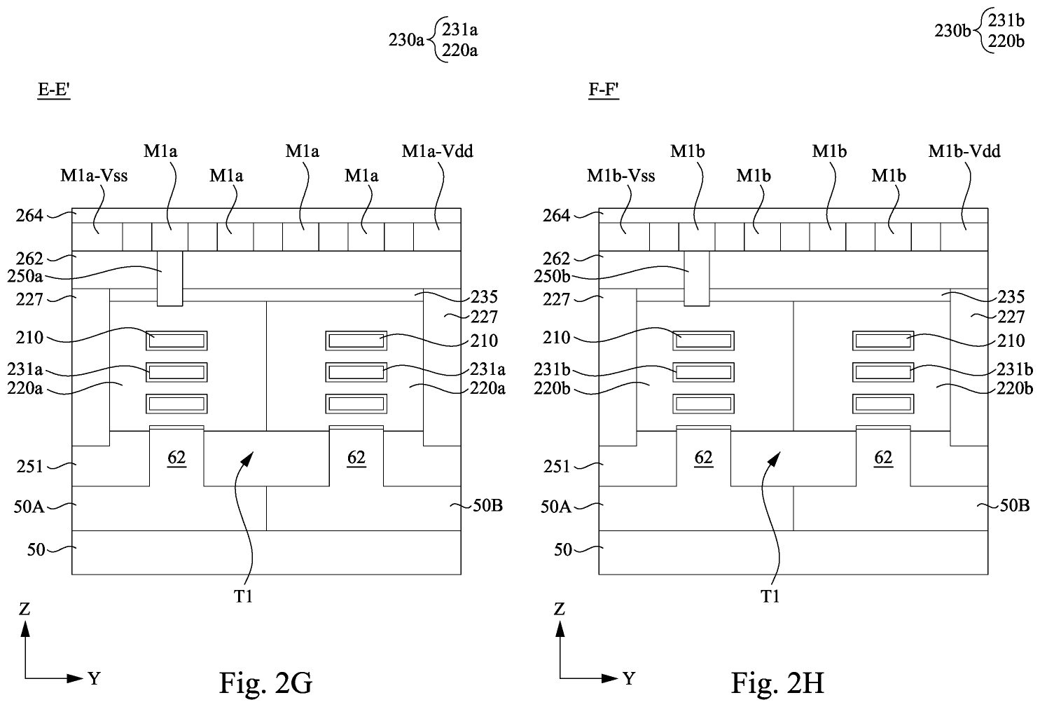

Reference is made to FIGS. 1-2H. FIG. 1 illustrates a layout diagram of logic circuits of a semiconductor structure according to some embodiments of the present disclosure. FIGS. 2A-2D, 2G, and 2H illustrate cross-sectional views obtained from reference cross-sections A-A′, B-B′, C-C′, D-D′, E-E′, F-F′ in FIG. 1. As shown in FIG. 1, a first circuit region 10A and a second circuit region 10B are arranged in a semiconductor structure 10. In FIGS. 2A and 2B, it should be noted that the configuration of the first circuit region 10A and the second circuit region 10B in the logic circuit 10 is used as an illustration, and not to limit the disclosure. In some embodiments, the row in the cell of the semiconductor structure 10 may include more logic cells or fewer logic cells than the layout shown in FIG. 1. Each logic cell provides a circuit or portion thereof, exemplary functionality provided by the cells includes, but are not limited to NAND, NOR, AND, XOR, XNOR, SACN, inverter, Flip-Flop, latch, and/or other suitable logic or storage functions. In some embodiments, the functionality of the second circuit region 10B can be different than the first circuit region 10A. In some embodiments, the functionality of the second circuit region 10B can be the same as the first circuit region 10A. Specifically, the particular type of logic gate is determined by coupling the gate, source, and drain of the NMOSFETs and PMOSFETs in a specific configuration. By way of example but not limiting the present disclosure, the first circuit region 10A may have a NAND circuit, and the second circuit region 10B may have an inverter.

In some embodiments, the first circuit region 10A and the second circuit region 10B may have cell heights H1 and H2 and cell widths W1 and W2. As shown in FIG. 1, the cell width W2 of the second circuit region 10B may be wider than the cell width W1 of the second circuit region 10B. In some embodiments, the cell width W2 of the second circuit region 10B may be the same as the cell width W1 of the first circuit region 10A. In some embodiments, the cell width W2 of the second circuit region 10B may be less than the cell width W1 of the first circuit region 10A. As shown in FIG. 1, the cell height H2 of the second circuit region 10B may be the same as the cell height H1 width W1 of the first circuit region 10A. In some embodiments, the cell height H2 of the second circuit region 10B may be the greater than the cell height H1 of the first circuit region 10A. In some embodiments, the cell height H2 of the second circuit region 10B may be less than the cell height H1 of the first circuit region 10A.

In some embodiments, the semiconductor structure 10 may include transistors over first conductivity type device regions 10C, 10D, and second conductivity type device regions 10E and 10F over a substrate 50 (see FIGS. 2A-2H). In some embodiments, the transistors in the first conductivity type device regions 10C and 10D may be NMOSFET transistors with silicon channel regions, and the transistors in the second conductivity type device regions 10E and 10F may be PMOSFET transistors with silicon channel regions. In some embodiments, the transistors may be GAA FETs. The silicon channel regions of the NMOS and PMOS transistors are formed by semiconductor sheets 210. The semiconductor sheets 210 are stacked along the Z-direction (not shown) and are wrapped by the gate electrode, and the Z-direction is perpendicular to the plane formed by the X-direction and Y-direction. Fins 62 (see FIGS. 2G and 2H) are semiconductor strips patterned in the substrate 50 below the semiconductor sheets 210.

A second conductivity type well 50A (see FIGS. 2A, 2B, 2G, and 2H) and a first conductivity type well 50B (see FIGS. 2C, 2D, 2G, and 2H) are formed in the substrate 50. The fins 62 can be upwardly protrude from the first and second conductivity type wells 50B and 50A. By way of example but not limiting the present disclosure, the second conductivity type well 50A may be a p-well, and the first conductivity type well 50B may be n-well. Shallow trench isolation (STI) structures 251 (see FIGS. 2G and 2H) can be formed over the substrate 50 and between adjacent fins 62. The STI structures 251 are disposed around at least a portion of the fins 62, such that at least a portion of the first and second semiconductor sheets 310, 210 protrude from between adjacent STI structures 251. In some embodiments, the top surfaces of the STI structures 251 are coplanar (within process variations) with the top surfaces of the fins 62. In some embodiments, the top surfaces of the STI structures 251 are above or below the top surfaces of the fins 62. The STI structures 251 separate the features of adjacent devices.

The semiconductor structure 10 can include gate structures 230a within the first circuit region 10A and gate structures 230b within the second circuit region 10B. The gate structure 230a can include a gate dielectric layer 231a (see FIGS. 2A, 2C, 2E, and 2G) wrapping around the second semiconductor sheets 210, and gate electrode layer 220a (see FIGS. 2A, 2C, 2E, and 2G) formed over the gate dielectric layer 231a. The gate structure 230b can include a gate dielectric layer 231b (see FIGS. 2B, 2D, 2F, and 2H) wrapping around the second semiconductor sheets 210, and gate electrode layer 220b (see FIGS. 2B, 2D, 2F, and 2H) formed over the gate dielectric layer 231b. The gate structures 230a and 230b can extend in the Y-direction. Also included in FIG. 1, spacers 233a and 233b are formed on sidewalls of the gate electrodes 220a and 220b.

As shown in FIG. 1, the gate electrodes 220a within the first circuit region 10A are connected to an overlying level (e.g., metal line M1a) through gate vias 250a, and the gate electrodes 220b within the second circuit region 10B are connected to an overlying level (e.g., metal line M1b) through gate vias 250b. In some embodiments, a source/drain region 218a (see FIGS. 2A, 2C, and 2E) between corresponding two of the gate electrodes 220a can be electrically coupled to an overlying metal line M1a through a source/drain contact 240a and a source/drain via 242a, and a source/drain region 218b (see FIGS. 2B, 2D, and 2F) between corresponding two of the gate electrodes 220a can be electrically coupled to an overlying metal line M1b through a source/drain contact 240b and a source/drain via 242b. In some embodiments, the source/drain region 218a within the first circuit region 10A can be electrically coupled to an overlying power supply voltage line M1a-Vdd/M1a-Vss through a power supply voltage contact 244a and a conductive via 246a, and the source/drain region 218b within the second circuit region 10B can be electrically coupled to an overlying power supply voltage line M1b-Vdd/M1b-Vss through a power supply voltage contact 244b and a conductive via 246b. In some embodiments, the power supply voltage contacts 244a and 244b can be interchangeably referred to source/drain contacts.

Throughout the description, the notations of metal lines may be followed by the metal line levels they are in, wherein the respective metal line level is placed in parenthesis. As shown in FIG. 1, metal lines disposed at the M1 level on the semiconductor structure 10 may include the power supply voltage lines M1a-Vdd, M1b-Vdd, M1a-Vss, and M1b-Vss, the metal lines M1a laterally between the power supply voltage lines M1a-Vdd and M1a-Vdd, and the metal lines M1b laterally between the power supply voltage lines M1b-Vdd and M1b-Vdd. The metal lines disposed at the M1 level of the semiconductor structure 10 may have lengthwise directions parallel to the X-direction (e.g., column direction). In some embodiments, the cells can be powered through the power supply voltage lines M1a-Vdd and M1b-Vdd, and the power supply voltage lines M1a-Vdd and M1b-Vdd can be interchangeably referred to as Vdd lines that can be provided with a positive power supply voltage Vdd. The power supply voltage lines M1a-Vss and M1b-Vss can be interchangeably referred to as Vss lines that can be provided with power supply voltage Vss, which may be an electrical ground. In some embodiments, the power supply voltage contacts 244a and 244b can be interchangeably referred to as Vss/Vdd contacts. In some embodiments, materials of the lines M1a, M1b, M1a-Vdd, M1b-Vdd, M1a-Vss, and M1b-Vss, the contact 244a and 244b, and/or the conductive via 246a, 246b, 248a, and 248b of the semiconductor structure may be made of Cu, Co, Ru, Pt, Al, W, Ti, TaN, TiN, or any combinations thereof.

In some embodiments, the layouts as shown in FIG. 1 can be represented by a plurality of masks generated by one or more processors and/or stored in one or more non-transitory computer-readable media. Other formats for representing the layout are within the scope of various embodiments. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

As shown in FIGS. 2A-2F, a dopant in the source/drain region 218a of the first conductivity type device region 10C (see FIG. 2A) has an opposite conductivity type to a dopant in the source/drain region 218a of the second conductivity type device region 10D (see FIG. 2C). For example, the source/drain region 218a of the first conductivity type device region 10C may have an n-type dopant, and the source/drain region 218a of the second conductivity type device region 10E may have a p-type dopant. Similarly, a dopant in the source/drain region 218b of the first conductivity type device region 10D see FIG. 2B) has an opposite conductivity type to a dopant in the source/drain region 218b of the second conductivity type device region 10F (see FIG. 2D). For example, the source/drain region 218b of the first conductivity type device region 10D may have an n-type dopant, and the source/drain region 218b of the second conductivity type device region 10F may have a p-type dopant. In some embodiments, the source/drain regions 218a and 218b of the first conductivity type device regions 10C and 10D (see FIGS. 2A and 2B) may include SiP, SiC, SiPC, SiAs, Si, or a combination thereof. In some embodiments, the source/drain regiona 218a and 218b of the first conductivity type device regions 10C and 10D may have a phosphorus concentration within a range from about 2E19/cm³ to about 3E21/cm³. In some embodiments, the source/drain regions 218a and 218b of the second conductivity type device regions 10E and 10F may have a boron concentration within a range from about 1E19/cm³ to about 6E20/cm³. In some embodiments, the source/drain regions 218a and 218b of the second conductivity type device regions 10E and 10F may have a Ge atomic percentage within a range of about 36% to about 85%. Dielectric layers 255a (see FIGS. 2A and 2C) are formed on bottoms of the source/drain regions 218a, and dielectric layers 255b (see FIGS. 2B and 2D) are formed on bottoms of the source/drain regions 218b.

In FIGS. 2A-2F, the gate spacers 233a are formed on the sidewalls of the gate electrode layers 220a and the gate spacers 233b are formed on the sidewalls of the gate electrode layers 220b. In some embodiments, the gate spacers 233a and 233b may be made of silicon nitride or silicon oxynitride, although any suitable material, such as low-dielectric constant (low-k) materials having a k-value less than about 3.5, may be utilized.

In FIGS. 2A-2F, inner spacers 236a within the first circuit region 10A can act as isolation features and may be formed between the source/drain regions 218a and the gate electrode layers 220a, and inner spacers 236b within the second circuit region 10B can act as isolation features and may be formed between the source/drain regions 218b and the gate electrode layers 220b. In some embodiments, the inner spacers 236a and 236b can be interchangeably referred to lower gate spacers, and the gate spacers 233a and 233b can be interchangeably referred to upper gate spacers or top gate spacers. In some embodiments, the inner spacers 236b within the second circuit region 10B can have greater lateral dimensions the inner spacers 236a within the first circuit region 10A. By way of example but not limiting the present disclosure, the inner spacers 236a and/or 236b may have a lateral dimension in a range from about 3 nm to about 12 nm. In some embodiments, the inner spacers 236 may be made of silicon nitride or silicon oxynitride, although any suitable material, such as low-dielectric constant (low-k) materials having a k-value less than about 3.5, may be utilized. In some embodiments, the inner spacers 236 may be air gaps. In some embodiments, the inner spacer 236a/236b may have a higher K (dielectric constant) value than the gate spacer 233a/233b.

In FIGS. 2A-2H, hard mask layers 235 are formed over the gate electrode layers 220a and 220b. In some embodiments, the hard mask layer 235 can be interchangeably referred to a gate top dielectric. In some embodiments, the hard mask layer 235 may be made of dielectric material, such as SiO₂, Si₃N₄, SiON, SiOC, SiOCN base dielectric material, or combinations thereof. In FIGS. 1, 2G and 2H, dielectric regions 227 can be formed on opposite ends of the gate electrode layers 220a and 220b. In some embodiments, each dielectric region 227 is a gate-cut structure for the gate structure, and the gate-cut structure is formed by a cut metal gate (CMG) process.

In FIGS. 2A-2C and 2F-2H, an inter-layer dielectric (ILD) layer 260 (see FIGS. 2B, 2D, and 2F) is formed between the gate electrode layers 220a and 220b and over the source/drain regions 218a and 218b. An ILD layer 262 is formed over the hard mask layers 235 and the ILD layer 260 and laterally surrounds the gate vias 250a and 250b and the source/drain vias 242a and 242b. An inter-metal dielectric (IMD) layer 264 is formed over the ILD layer 262 and can provide electrical insulation as well as structural support for the various features therein, such as the metal lines M1a and M1b, the power supply voltage lines M1a-Vdd, M1v-Vdd, M1a-Vss, and M1b-Vss. In some embodiments, the ILD layer 260, the ILD layer 262, and/or the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

Reference is made to FIGS. 2E and 2F. FIGS. 2E and 2F illustrate schematic cross-sectional views of a semiconductor structure 20 corresponding to FIGS. 2C and 2D. While FIGS. 2E and 2F show embodiments of the semiconductor structure 20 with different structure configurations than the semiconductor structure 10 in FIGS. 2A-2D, 2G, and 2H. In addition, the present disclosure may repeat reference numerals and/or letters in the various examples. This repetition is for the purpose of simplicity and clarity and does not in itself dictate a relationship between the various embodiments and/or configurations discussed. As shown in FIGS. 2E and 2F, the difference between the embodiment in FIGS. 2E and 2F and the embodiment in FIGS. 2A-2D, 2G, and 2H is in that there is no dielectric layer (e.g., dielectric layers 255a and 255b) between the source/drain regions 218a and the substrate 50, and between the source/drain regions 218b and the substrate 50 within the second conductivity type device region 10D (see FIG. 1).

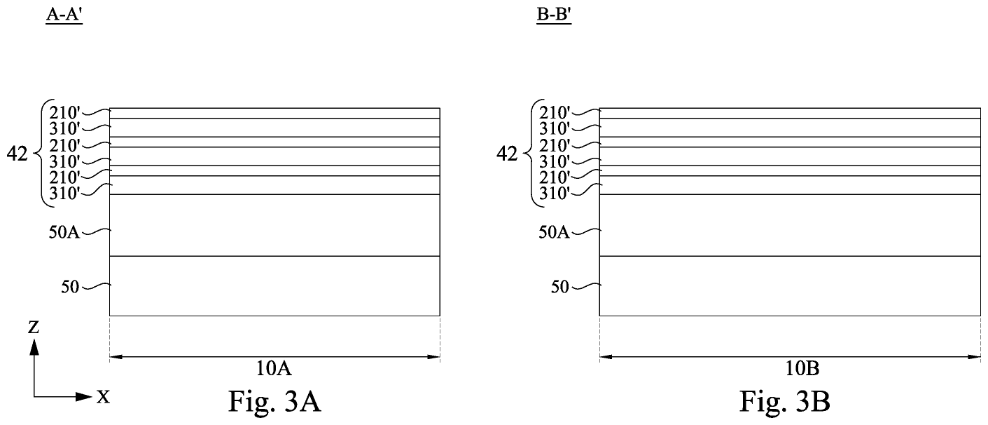

Reference is made to FIGS. 3A to 17B. FIGS. 3A to 17B illustrate the cross-sectional views of intermediate stages in the formation of a semiconductor structure in accordance with some embodiments. FIGS. 3A, 4A, 5A, 6A, 7A, 8A, 9A, 10A, 11A, 12A, 13A, 14A, 15A, 16A, and 17A illustrate cross-sectional views obtained from the reference cross-section A-A′ in FIG. 1 of intermediate stages in the formation of a semiconductor structure in accordance with some embodiments. FIGS. 3B, 4B, 5B, 6B, 7B, 8B, 9B, 10B, 11B, 12B, 13B, 14B, 15B, 16B, and 17B illustrate cross-sectional views obtained from the reference cross-section B-B′ in FIG. 1 of intermediate stages in the formation of a semiconductor structure in accordance with some embodiments.

Reference is made to FIGS. 3A and 3B. A substrate 50 is provided for forming nano-FETs. The substrate 50 may be a semiconductor substrate, such as a bulk semiconductor, a semiconductor-on-insulator (SOI) substrate, or the like, which may be doped (e.g., with a p-type or an n-type impurity) or undoped. The substrate 50 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like. A second conductivity type well 50A and a first conductivity type well 50B can be formed in the substrate 50.

Subsequently, multi-layer stacks 42 can be formed over the substrate 50 within the first circuit region 10A (see FIG. 3A) and the second circuit region 10B (see FIG. 3B). The multi-layer stack 42 includes alternating first semiconductor layers 310′ and second semiconductor layers 210′. The first semiconductor layers 310′ formed of a first semiconductor material, and the second semiconductor layers 210′ are formed of a second semiconductor material. The semiconductor materials may each be selected from the candidate semiconductor materials of the substrate 50. In some embodiments, the multi-layer stack 42 includes three layers of each of the first semiconductor layers 310′ and the second semiconductor layers 210′. It should be appreciated that the multi-layer stack 42 may include any number of the first semiconductor layers 310′ and the second semiconductor layers 210′.

In some embodiments, and as will be subsequently described in greater detail, the first semiconductor layers 310′ will be removed and the second semiconductor layers 210′ will patterned to form channel regions for the nano-FETs. The first semiconductor layers 310′ are sacrificial layers (or dummy layers), which will be removed in subsequent processing to expose the top surfaces and the bottom surfaces of the second semiconductor layers 210′. The first semiconductor material of the first semiconductor layers 310′ is a material that has a high etching selectivity from the etching of the second semiconductor layers 210′, such as silicon germanium. The second semiconductor material of the second semiconductor layers 210′ is a material suitable for both n-type and p-type devices, such as silicon.

In some embodiments, the first semiconductor material of the first semiconductor layers 310′ may be made of a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 210′ may be made of a material, such as silicon, silicon carbide, a III-V compound semiconductor, a II-VI compound semiconductor, or the like. The first semiconductor material and the second semiconductor material may have a high etching selectivity from the etching of one another. Each of the layers of the multi-layer stack 42 may be grown by a process such as vapor phase epitaxy (VPE) or molecular beam epitaxy (MBE), deposited by a process such as chemical vapor deposition (CVD) or atomic layer deposition (ALD), or the like. In some embodiments, the multi-layer stack 42 may have a thickness in a range from about 30 to 120 nm, such as about 30, 40, 50, 60, 70, 80, 90, 100, 110, or 120 nm. In some embodiments, each of the layers may have a small thickness, such as a thickness in a range of about 5 nm to about 40 nm. In some embodiments, some layers (e.g., the second semiconductor layers 210′) are formed to be thinner than other layers (e.g., the first semiconductor layers 310′). For example, in embodiments in which the first semiconductor layers 310′ are sacrificial layers (or dummy layers) and the second semiconductor layers 210′ are patterned to form channel regions for the nano-FETs.

Subsequently, trenches T1 (see FIGS. 2G and 2H) are patterned in the substrate 50 and the multi-layer stacks 42 to form fins 62, first semiconductor sheets 310, and second semiconductor sheets 210 within the first circuit region 10A (see FIG. 3A) and the second circuit region 10B (see FIG. 3B). The fins 62 are semiconductor strips patterned in the substrate 50. The first semiconductor sheets 310 and the second semiconductor sheets 210 include the remaining portions of the first semiconductor layers 310′ and the second semiconductor layers 210′, respectively. The trenches T1 may be patterned by any acceptable etch process, such as a reactive ion etch (RIE), neutral beam etch (NBE), the like, or a combination thereof. The etching may be anisotropic.

The fins 62 (see FIGS. 2G and 2H) and the first and second semiconductor sheets 310, 210 may be patterned by any suitable method. For example, the fins 62 and the first and second semiconductor sheets 310, 210 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as masks to pattern the fins 62 and the first and second semiconductor sheets 310, 210. In some embodiments, the mask (or other layer) may remain on the first and second semiconductor sheets 310, 210. The fins 62 and the first and second semiconductor sheets 310, 210 may each have widths in a range of about 8 nm to about 40 nm. In some embodiments, the fins 62 and the first and second semiconductor sheets 310, 210 have substantially equal widths.

STI structures 251 (see FIGS. 2G and 2H) are formed over the substrate 50 and between adjacent fins 62 (see FIGS. 2G and 2H). The STI structures 251 are disposed around at least a portion of the fins 62, such that at least a portion of the first and second semiconductor sheets 310, 210 protrude from between adjacent STI structures 251. In some embodiments, the top surfaces of the STI structures 251 are coplanar (within process variations) with the top surfaces of the fins 62. In some embodiments, the top surfaces of the STI structures 251 are above or below the top surfaces of the fins 62. The STI structures 251 separate the features of adjacent devices. The STI structures 251 may be formed by any suitable method. For example, an insulation material can be formed over the substrate 50 and the first and second semiconductor sheets 310, 210, and between adjacent fins 62. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In an embodiment, the insulation material is formed such that excess insulation material covers the first and second semiconductor sheets 310, 210. Although the STI structures 251 are each illustrated as a single layer, some embodiments may utilize multiple layers. For example, in some embodiments a liner (not separately illustrated) may first be formed along surfaces of the substrate 50, the fins 62, and the first and second semiconductor sheets 310, 210. Thereafter, a fill material, such as those previously described may be formed over the liner.

A removal process is then applied to the insulation material to remove excess insulation material over the first and second semiconductor sheets 310, 210. In some embodiments, a planarization process such as a chemical mechanical polish (CMP), an etch-back process, combinations thereof, or the like may be utilized. In embodiments in which a mask remains on the first and second semiconductor sheets 310, 210, the planarization process may expose the mask or remove the mask. After the planarization process, the top surfaces of the insulation material and the mask (if present) or the first and second semiconductor sheets 310, 210 are coplanar (within process variations). Accordingly, the top surfaces of the mask (if present) or the first and second semiconductor sheets 310, 210 are exposed through the insulation material. In some embodiments, no mask remains on the first and second semiconductor sheets 310, 210. The insulation material is then recessed to form the STI structures 251. The insulation material is recessed, such as in a range from about 30 nm to about 80 nm, such that at least a portion of the first and second semiconductor sheets 310, 210 protrude from between adjacent portions of the insulation material. Further, the top surfaces of the STI structures 251 (see FIGS. 2G and 2H) may have a flat surface as illustrated, a convex surface, a concave surface (such as dishing), or a combination thereof. The top surfaces of the STI structures 251 may be formed flat, convex, and/or concave by an appropriate etch. The insulation material may be recessed using any acceptable etching process, such as one that is selective to the material of the insulation material (e.g., selectively etches the insulation material of the STI structures 251 at a faster rate than the materials of the fins 62 and the first and second semiconductor sheets 310, 210). For example, an oxide removal may be performed using dilute hydrofluoric (dHF) acid.

The process previously described is just one example of how the fins 62 (see FIGS. 2G and 2H) and the first and second semiconductor sheets 310, 210 may be formed within the first circuit regions 10A and 10B. In some embodiments, the fins 62 and/or the first and second semiconductor sheets 310, 210 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the first and second semiconductor sheets 310, 210. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together. In some embodiments, the second semiconductor sheet 210 can be interchangeably referred to a channel region, channel pattern, or a channel layer.

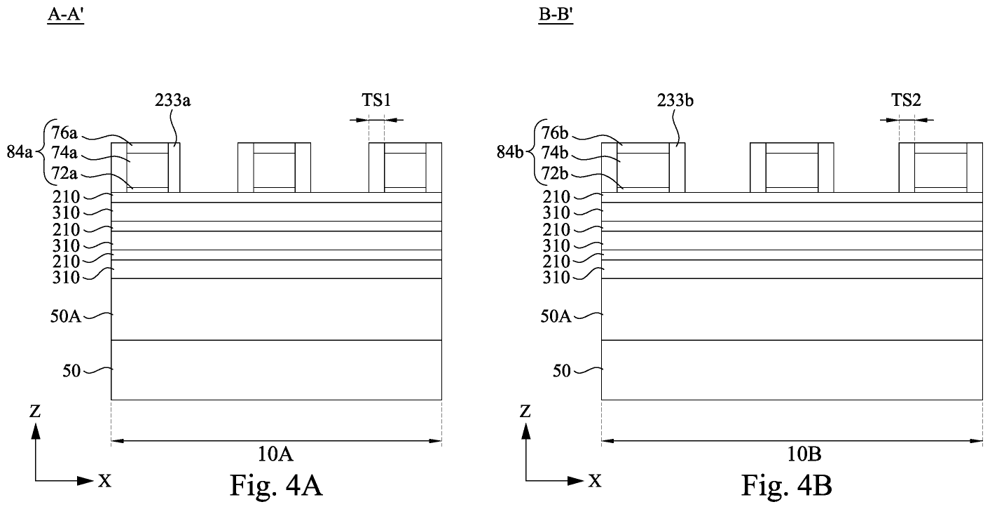

Reference is made to FIGS. 4A and 4B. A dummy dielectric layer, a dummy gate layer, and a mask layer are sequentially formed on the fins 62 and the first and second semiconductor sheets 310, 210 within the first and second circuit regions 10A and 10B. The dummy dielectric layer is formed on the fins 62 and the first and second semiconductor sheets 310, 210. The dummy dielectric layer may be formed of a dielectric material such as silicon oxide, silicon nitride, a combination thereof, or the like, which may be deposited or thermally grown according to acceptable techniques. Subsequently, a dummy gate layer is formed over the dummy dielectric layer. Subsequently, a mask layer is formed over the dummy gate layer. The dummy gate layer may be deposited over the dummy dielectric layer and then planarized, such as by a CMP. The mask layer may be deposited over the dummy gate layer. The dummy gate layer may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer may be formed of material(s) that have a high etching selectivity from the etching of insulation materials, e.g., the STI structures 251 and/or the dummy dielectric layer. The mask layer may be formed of a dielectric material such as silicon nitride, silicon oxynitride, or the like. In some embodiments, the dummy dielectric layer covers the fins 62, the first and second semiconductor sheets 310, 210, and the STI structures 251, such that the dummy dielectric layer extends over the STI structures 251 and between the dummy gate layer and the STI structures 251. In another embodiment, the dummy dielectric layer covers only the fins 62 and the first and second semiconductor sheets 310, 210.

The mask layer is patterned using acceptable photolithography and etching techniques to form masks 76a (see FIG. 4A) within the first circuit region 10A and masks 76b (see FIG. 4B) within the second circuit region 10B. The pattern of the masks 76a and 76b are then transferred to the dummy gate layer by any acceptable etching technique to form dummy gates 74a (see FIG. 4A) within the first circuit region 10A and dummy gates 74b (see FIG. 4B) within the second circuit region 10B. The pattern of the masks 76a and 76b may optionally be further transferred to the dummy dielectric layer by any acceptable etching technique to form dummy dielectrics 72a (see FIG. 4A) within the first circuit region 10A and dummy dielectrics 72b (see FIG. 4B) within the second circuit region 10B. The dummy gate 74a and the dummy dielectric 72a within the first circuit region 10A may be collectively referred to as a dummy gate structure 84a (see FIG. 4A), and the dummy gate 74b and the dummy dielectric 72b within the second circuit region 10B may be collectively referred to as a dummy gate structure 84b (see FIG. 4B). The dummy gate structures 84a and 84b cover portions of the first and second semiconductor sheets 310, 210 that will be exposed in subsequent processing to form channel regions. Specifically, the dummy gate structures 84a and 84b extend along the portions of the second semiconductor sheets 210 that will be patterned to form channel regions within the first and second circuit regions 10A and 10B. The pattern of the masks 76a and 76b may be used to physically separate adjacent dummy gate structures 84a and 84b. The dummy gate structures 84a and 84b may also have lengthwise directions substantially perpendicular (within process variations) to the lengthwise directions of the fins 62. The masks 76 can optionally be removed after patterning, such as by any acceptable etching technique.

Gate spacers 233a (see FIG. 4A) are formed over the first and second semiconductor sheets 310, 210, on exposed sidewalls of the masks 76a, the dummy gates 74a, and the dummy dielectrics 72a, and gate spacers 233b (see FIG. 4B) are formed over the first and second semiconductor sheets 310, 210, on exposed sidewalls of the masks 76b, the dummy gates 74b, and the dummy dielectrics 72b. In some embodiments, the gate spacers 233a and 233b can be interchangeably referred to top spacers or upper gate spacers. In some embodiments, the gate spacer 233a may have a lateral dimension (or thickness) TS1 in a lengthwise direction of the semiconductor sheet 210, and the lateral dimension TS1 can be in a range from about 3 nm to about 12 nm, such as about 3, 4, 5, 6, 7, 8, 9, 10, 11, or 12 nm. In some embodiments, the gate spacer 233a may have a lateral dimension (or thickness) TS2 in a lengthwise direction of the semiconductor sheet 210, and the lateral dimension TS2 can be in a range from about 3 nm to about 12 nm, such as about 3, 4, 5, 6, 7, 8, 9, 10, 11, or 12 nm. At the time the gate spacers 233a are formed, the gate spacers 233b are also formed simultaneously. Because of simultaneous formation of the gate spacers 233a and the gate spacers 233b, the gate spacers 233b are formed of same material(s) as the gate spacers 233a. In some embodiments, the lateral dimension TS2 of the gate spacer 233b may be greater than the lateral dimension TS1 of the gate spacer 233a. By way of example but not limiting the present disclosure, the lateral dimension TS2 of the gate spacer 233b can be greater than the lateral dimension TS1 of the gate spacer 233a within a range of about 0.5-5 nm. In some embodiments, the lateral dimension TS2 of the gate spacer 233b may be the same as the lateral dimension TS1 of the gate spacer 233a.

In some embodiments, the gate spacer 233a and/or the gate spacer 233b may include multiple dielectric material and selected from a group consist of SiO₂, Si₃N₄, carbon doped oxide, nitrogen doped oxide, porous oxide, air gap, or combinations thereof. The gate spacers 233a and 233b may be formed by conformally depositing one or more dielectric material(s) and subsequently etching the dielectric material(s). Acceptable dielectric materials may include silicon oxide, silicon nitride, silicon oxynitride, silicon oxycarbonitride, or the like, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gate structures 84a and 84b (thus forming the gate spacers 233a and 233b).

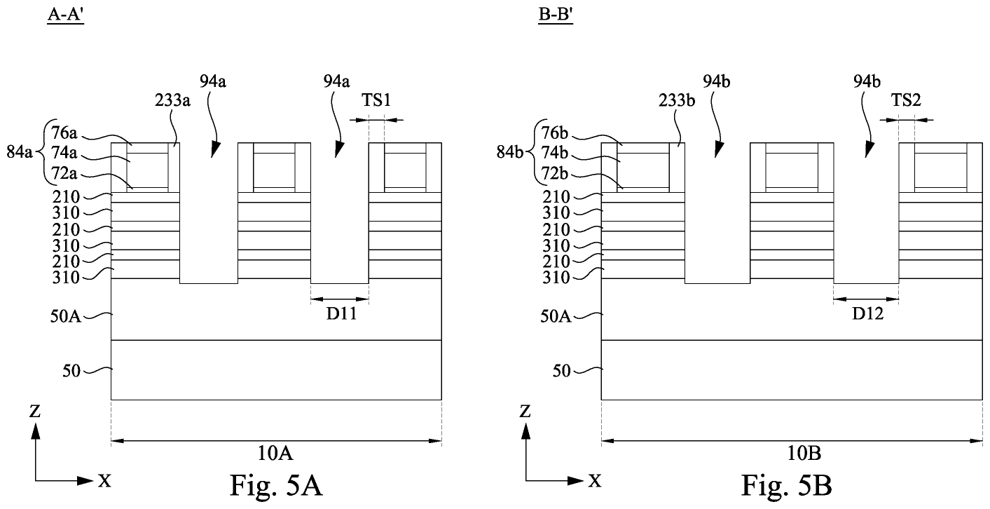

Reference is made to FIGS. 5A and 5B. Source/drain recesses 94a (see FIG. 5A) are formed in the first and second semiconductor sheets 310, 210 within the first circuit region 10A, and source/drain recesses 94b (see FIG. 5B) are formed in the first and second semiconductor sheets 310, 210 within the second circuit region 10B. In some embodiments, the source/drain recesses 94a and 94b extend through the first and second semiconductor sheets 310, 210 and into the fins 62. In some embodiments, the fins 62 may be etched such that bottom surfaces of the source/drain recesses 94a and 94b are disposed below the top surfaces of the STI structures 251. The source/drain recesses 94a and 94b may be formed by etching the first and second semiconductor sheets 310, 210 using an anisotropic etching process, such as a RIE, a NBE, or the like. The gate spacers 233a and 233b and the dummy gate structures 84a and 84b collectively mask portions of the fins 62 and/or the first and second semiconductor sheets 310, 210 during the etching processes used to form the source/drain recesses 94a and 94b. A single etch process may be used to etch each of the first and second semiconductor sheets 310, 210, or multiple etch processes may be used to etch the first and second semiconductor sheets 310, 210. Timed etch processes may be used to stop the etching of the source/drain recesses 94 after the source/drain recesses 94a and 94b reach a desired depth. In some embodiments, the source/drain recess 94a has a lateral dimension (or width) D11 (see FIG. 5A) in a lengthwise direction of the semiconductor sheet 210, the source/drain recess 94b has a lateral dimension (or width) D12 (see FIG. 5B) in a lengthwise direction of the semiconductor sheet 210, and the lateral dimension D12 can be greater than the lateral dimension D11. In some embodiments, the lateral dimension D12 may be the same as the lateral dimension D11.

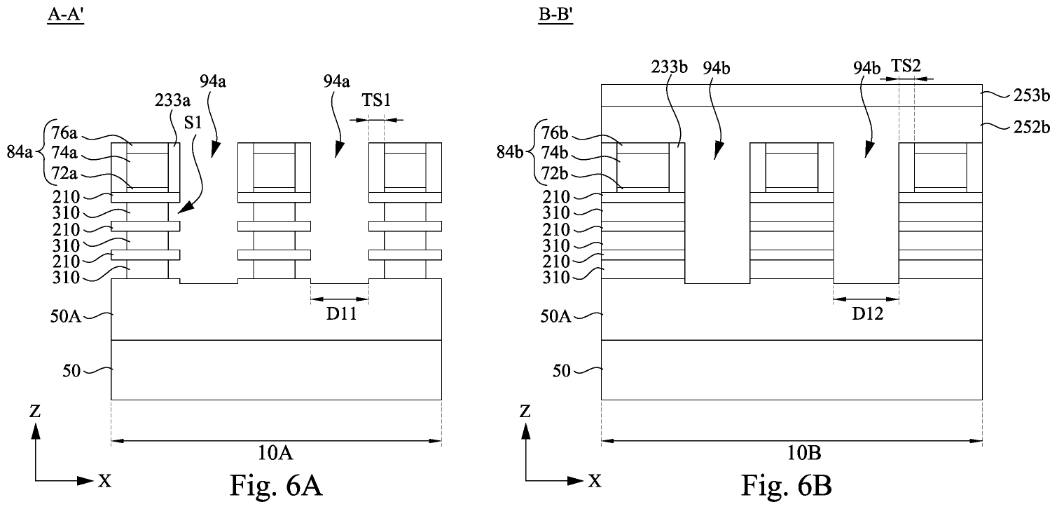

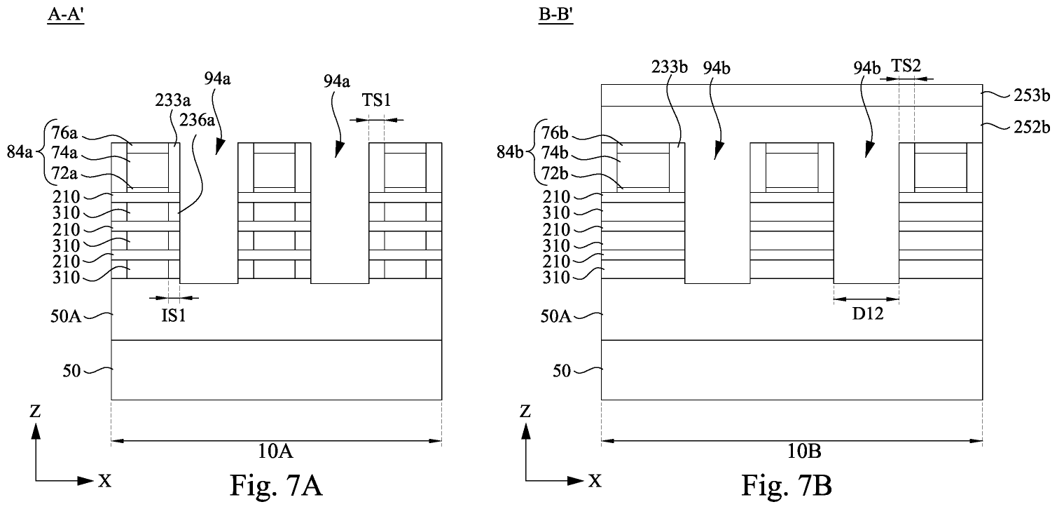

Reference is made to FIGS. 6A-7B. A dielectric material 252b (see FIG. 6B), e.g. spin-on-glass (SOG), can be formed, covering the dummy gate structures 84b and gate spacers 233b within the second circuit region 10B and filling the source/drain recesses 94b, and exposing the dummy gate structures 84a and gate spacers 233a within the first circuit region 10A. A photoresist 253b can be defined over the dielectric material 252b. The dielectric material 252b and the photoresist 253b can be provided for forming inner spacers 236a within the first circuit region 10A. The dielectric material 252b and the photoresist 253b can be defined by, for example, a spin-on process, a photolithographic process, and an etching process.

Subsequently, inner spacers 236a (see FIG. 7A) are formed on sidewalls of the remaining portions of the first semiconductor sheets 310, e.g., those sidewalls exposed by the source/drain recesses 94a. As will be subsequently described in greater detail, source/drain regions will be subsequently formed in the source/drain recesses 94a, and the first semiconductor sheets 310 will be subsequently replaced with corresponding gate structures. The inner spacers 236a act as isolation features between the subsequently formed source/drain regions and the subsequently formed gate structures. Further, the inner spacers 236a may be used to substantially prevent damage to the subsequently formed source/drain regions by subsequent etching processes, such as etching processes used to subsequently remove the first semiconductor sheets 310. In some embodiments, the inner spacers 236a can be interchangeably referred to lower gate spacers. In some embodiments, the inner spacers 236a may have a lateral dimension (or thickness) IS1 in a lengthwise direction of the semiconductor sheet 210, and the lateral dimension IS1 can be in a range from about 3 nm to about 12 nm, such as about 3, 4, 5, 6, 7, 8, 9, 10, 11, or 12 nm.

As an example to form the inner spacers 236a, the source/drain recesses 94a can be laterally expanded. Specifically, portions of the sidewalls of the first semiconductor sheets 310 exposed by the source/drain recesses 94a may be recessed to form recesses S1. Although sidewalls of the first semiconductor sheets 310 are illustrated as being straight, the sidewalls may be concave or convex. The sidewalls may be recessed by any acceptable etching process, such as one that is selective to the material of the first semiconductor sheets 310 (e.g., selectively etches the material of the first semiconductor sheets 310 at a faster rate than the material of the second semiconductor sheets 210). The etching may be isotropic. For example, when the second semiconductor sheets 210 are formed of silicon and the first semiconductor sheets 310 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94a and recess the sidewalls of the first semiconductor sheets 310. The inner spacers 236a can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. In some embodiments, the inner spacer 236a may have a higher K (dielectric constant) value than the gate spacer 233a. In some embodiments, the material of inner spacer is selected from a group including SiO₂, Si₃N₄, SiON, SiOC, SiOCN base dielectric material, air gap, or combinations thereof. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 236a are illustrated as being flush with respect to the sidewalls of the gate spacers 233a, the outer sidewalls of the inner spacers 236a may extend beyond or be recessed from the sidewalls of the gate spacers 233a. In other words, the inner spacers 236a may partially fill, completely fill, or overfill the sidewall recesses. Moreover, although the sidewalls of the inner spacers 236a are illustrated as being straight, the sidewalls of the inner spacers 236a may be concave or convex. After the forming of the inner spacer 236a, the dielectric material 252b and the photoresist 253b are removed.

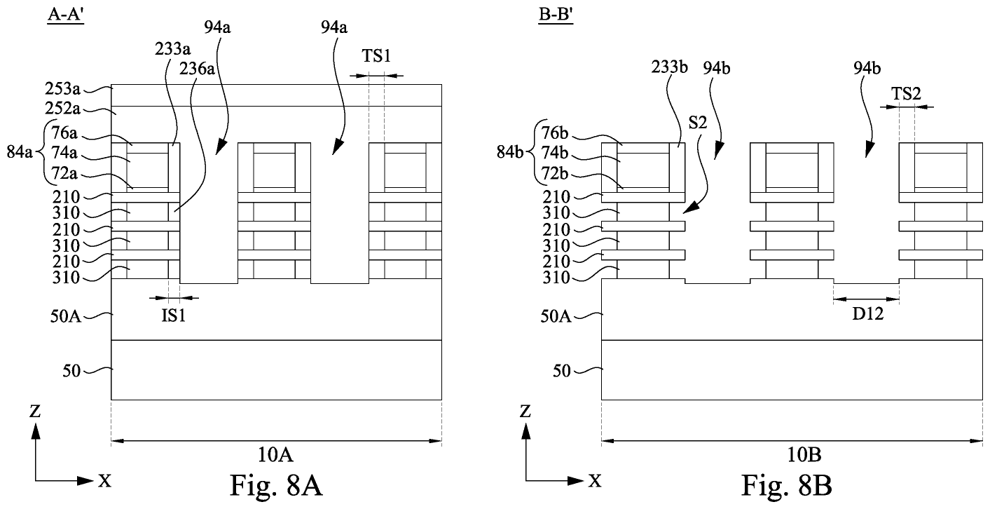

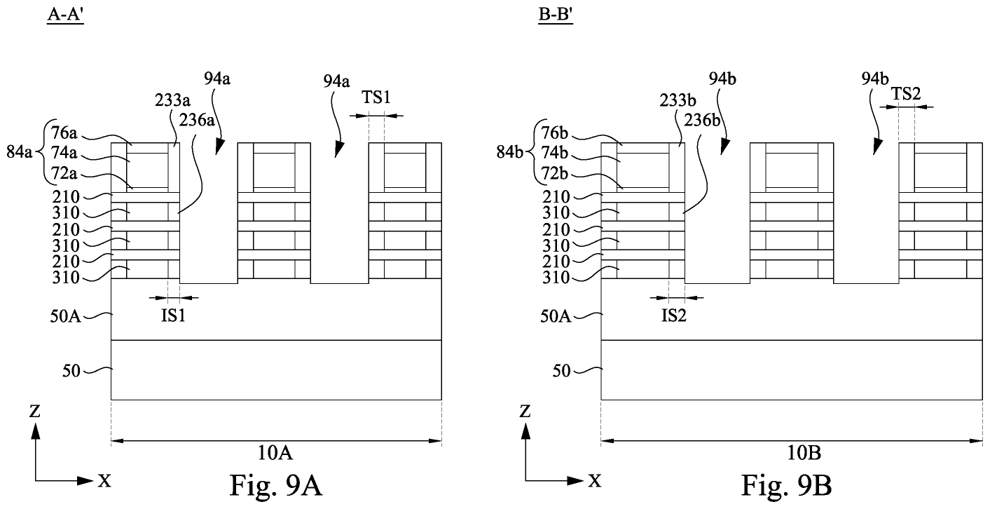

Reference is made to FIGS. 8A-9B. A dielectric material 252a (see FIG. 8A), e.g. spin-on-glass (SOG), can be formed, covering the dummy gate structures 84a and gate spacers 233a within the first circuit region 10A and filling the source/drain recesses 94a, and exposing the dummy gate structures 84b and gate spacers 233b within the second circuit region 10B. A photoresist 253a can be defined over the dielectric material 252b. The dielectric material 252a and the photoresist 253a can be provided for forming inner spacers 236a within the first circuit region 10A. The dielectric material 252a and the photoresist 253a can be defined by, for example, a spin-on process, a photolithographic process, and an etching process.

Subsequently, inner spacers 236b (see FIG. 9B) are formed on sidewalls of the remaining portions of the first semiconductor sheets 310, e.g., those sidewalls exposed by the source/drain recesses 94b. As will be subsequently described in greater detail, source/drain regions will be subsequently formed in the source/drain recesses 94b, and the first semiconductor sheets 310 will be subsequently replaced with corresponding gate structures. The inner spacers 236b act as isolation features between the subsequently formed source/drain regions and the subsequently formed gate structures. Further, the inner spacers 236b may be used to substantially prevent damage to the subsequently formed source/drain regions by subsequent etching processes, such as etching processes used to subsequently remove the first semiconductor sheets 310. In some embodiments, the inner spacers 236b can be interchangeably referred to lower gate spacers. In some embodiments, the inner spacers 236b may have a lateral dimension (or thickness) IS2 in a lengthwise direction of the semiconductor sheet 210, and the lateral dimension IS2 can be in a range from about 3 nm to about 12 nm, such as about 3, 4, 5, 6, 7, 8, 9, 10, 11, or 12 nm. As shown in FIGS. 9A and 9B, the lateral dimension IS2 of the inner spacer 236b is greater than the lateral dimension IS1 of the inner spacer 236a. In some embodiments, the lateral dimension IS2 of the inner spacer 236b is at least 5% greater than the lateral dimension IS1 of the inner spacer 236a. By way of example but not limiting the present disclosure, a ratio of the lateral dimension IS2 to the lateral dimension IS1 is in a range from about 1.05-1.3, such as about 1.05, 1.06, 1.08, 1.1, 1.12, 1.14, 1.16, 1.18, 1.2, 1.22, 1.24, 1.26, 1.28, or 1.3. In some embodiments, the lateral dimension IS2 of the inner spacer 236b can be greater than the lateral dimension TS2 (see FIG. 4B) of the gate spacer 233b.

As an example to form the inner spacers 236a, the source/drain recesses 94b can be laterally expanded. Specifically, portions of the sidewalls of the first semiconductor sheets 310 exposed by the source/drain recesses 94b may be recessed to form recesses S2. Although sidewalls of the first semiconductor sheets 310 are illustrated as being straight, the sidewalls may be concave or convex. The sidewalls may be recessed by any acceptable etching process, such as one that is selective to the material of the first semiconductor sheets 310 (e.g., selectively etches the material of the first semiconductor sheets 310 at a faster rate than the material of the second semiconductor sheets 210). The etching may be isotropic. For example, when the second semiconductor sheets 210 are formed of silicon and the first semiconductor sheets 310 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94b and recess the sidewalls of the first semiconductor sheets 310. The inner spacers 236b can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. In some embodiments, the inner spacer 236b may have a higher K (dielectric constant) value than the gate spacer 233b. In some embodiments, the material of inner spacer is selected from a group including SiO₂, Si₃N₄, SiON, SiOC, SiOCN base dielectric material, air gap, or combinations thereof. The insulating material may be deposited by a conformal deposition process, such as ALD, CVD, or the like. The etching of the insulating material may be anisotropic. For example, the etching process may be a dry etch such as a RIE, a NBE, or the like. In some embodiments, the outer sidewalls of the inner spacers 236b may extend beyond or be recessed from the inner sidewalls of the gate spacers 233b. Moreover, although the sidewalls of the inner spacers 236b are illustrated as being straight, the sidewalls of the inner spacers 236b may be concave or convex. After the forming of the inner spacer 236b, the dielectric material 252a and the photoresist 253a are removed.

With respect to the depicted formation processes of inner spacers 236a and 236b in FIGS. 6A-9B, an alternative method may be employed in other embodiments. Specifically, the portions of the first semiconductor sheets 310, exposed by the source/drain recesses 94a and 94b, could be simultaneously recessed. This procedure omits the need for forming dielectric materials 252a and 252b, leading to the forming of recesses S1 in the first circuit region 10A and recesses S2 in the second circuit region 10B. Following this procedure, a dielectric material can be formed to cover the dummy gate structures 84a and gate spacers 233a within the first circuit region 10A, while also filling the source/drain recesses 94a. Simultaneously, the dielectric material leaves the dummy gate structures 84b and gate spacers 233b within the second circuit region 10B exposed. The subsequent step involves further recessing the recesses S2 located in the second circuit region 10B. This is followed by the removal of the dielectric material covering the dummy gate structures 84a and gate spacers 233a within the first circuit region 10A. The following step in this alternative formation process includes the concurrent formation of inner spacers 236a and 236b within recesses S1 and S2. The method applied here can be similarly to the process described in FIGS. 6A-9B.

With respect to the depicted formation processes of inner spacers 236a and 236b in FIGS. 6A-9B, another alternative method may be employed in other embodiments. Specifically, the source/drain recesses 94b within the second circuit region 10B are wider than the source/drain recesses 94a in the first circuit region 10A. The exposed portions of the first semiconductor sheets 310 from the source/drain recesses 94a and 94b can be concurrently recessed. In the process of etching, the etchant is capable of entering the source/drain recesses more readily when these recesses are wider. As such, in the second circuit region 10B, the etchant can access and etch the semiconductor sheets 310 more efficiently due to the larger dimensions of the source/drain recesses 94b than the source/drain recesses 94a. Therefore, the sidewalls of the first semiconductor sheets 310, which are exposed by the wider source/drain recesses 94b, can be recessed more substantially. This leads to the formation of larger recesses, S2, within the second circuit region 10B. Conversely, in the first circuit region 10A, the relatively smaller source/drain recesses 94a result in a less substantial etching and, hence, smaller recesses S1. This procedure omits the need for forming dielectric materials 252a and 252b, leading to the recesses S1 in the first circuit region 10A and the recesses S2 in the second circuit region 10B. The following step in this alternative formation process includes the concurrent formation of inner spacers 236a and 236b within recesses S1 and S2. The method applied here can be similarly to the process described in FIGS. 6A-9B.

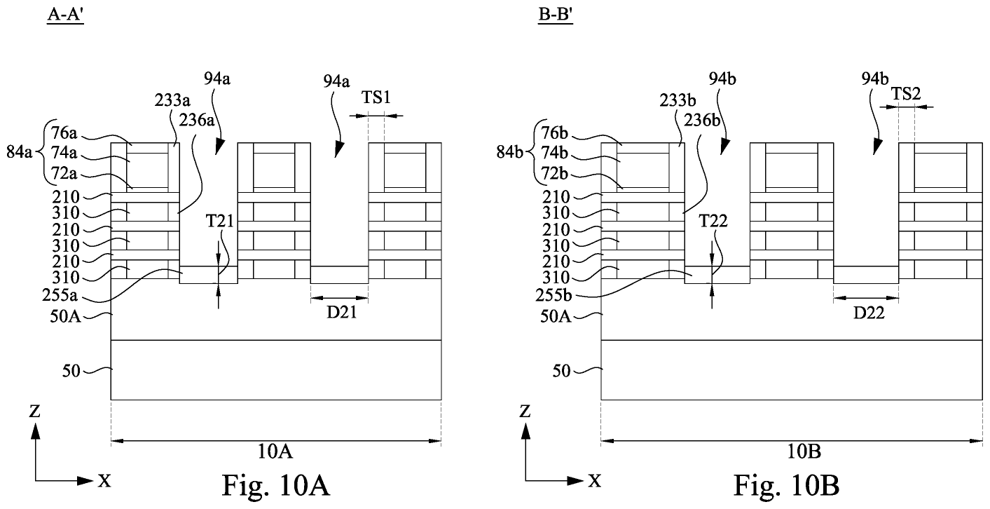

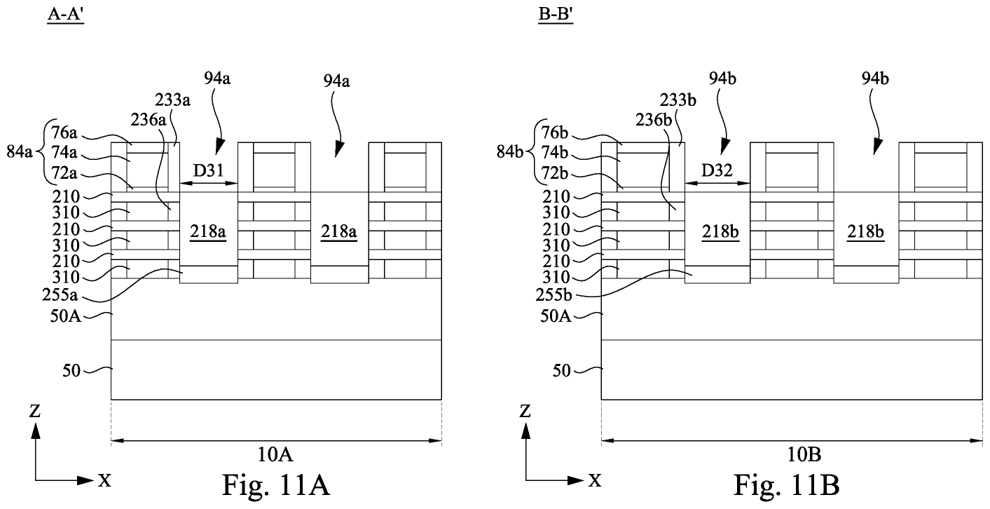

Reference is made to FIGS. 10A and 10B. Dielectric layers 255a are formed on bottoms of the source/drain recesses 94a where source/drain regions 218a (see FIG. 11A) will be subsequently formed thereon, and dielectric layers 255b are formed on bottoms of the source/drain recesses 94b where source/drain regions 218b (see FIG. 11B) will be subsequently formed thereon. In particular, a selective deposition process may include a deposition step to deposit the dielectric material over the substrate 50 and a sputter step to remove the dielectric material deposited on sidewalls of the recesses 94a and 94b and an upper surface above the substrate 50, so as to leave the deposited dielectric material on a lower surface above the substrate 50. In some embodiments, the selective deposition process may be performed by an inductively coupled plasma (ICP) tool or a capactitively coupled plasma (CCP) tool. In some embodiments, the deposition gas used in the selective deposition process may include, for example, a silicon source gas, such as silicon tetrachloride gas, SiCl₄, and an oxygen source gas, such as molecular oxygen gas, O₂, in plasma state to form a silicon oxide layer over the substrate 50. In some embodiments, the deposition gas used in the selective deposition process P3 may include, for example, a fluorocarbon (CₓF_{y}) source gas, such as C₄F₆ and/or C₄F₈, and an oxygen source gas, such as molecular oxygen gas, O₂, in plasma state to form a CₓF_{y} layer over the substrate 50. In some embodiments, the deposition gas used in the selective deposition process may include a mixture of BC1₃ and N₂ to deposit boron or boron nitride; a mixture of BC1₃, CH₄ and H₂ to deposit boron carbide. In some embodiments, sputter etching caused by plasmas in the selective deposition process may provide a higher sputter etch rate at the dielectric material on the sidewalls of the recesses 94a and 94b and the upper surface above the substrate 50 than on the lower surface above the substrate 50, such that the net effect of the deposition and sputter etching in the selective deposition process leads to the dielectric material remaining on the bottoms of the recesses 94a and 94b and absent on the sidewalls of the recesses 94a and 94b and the upper surface above the substrate 50. In some embodiments, the deposition and sputter etching in the selective deposition process may be performed in-situ or ex-situ.

In some embodiments, the dielectric layers 255a and/or 255b can be made of a different material than the inner spacers 236a and/or 236b. In some embodiments, the dielectric layer 255a and/or 255b can be made of a same material as the inner spacer 236a and/or 236b. In some embodiments, the dielectric layers 255a and 255b can be formed during a same process as forming the inner spacer 236, in which the material to form the inner spacers 236a and 236b can be remained at the bottoms of the recesses 94a and 94b to act as the dielectric layers 255a and 255b. In some embodiments, the dielectric layers 255a and 255b can be made of an oxide-containing material (e.g., SiO₂), a nitrogen-containing material (e.g., SiON, SiN, Si₃N₄), a carbon-containing material (e.g., SiOC, SIOCN), the like, or combinations thereof. In some embodiments, the dielectric layers 255a and 255b may be made of a material having a dielectric constant greater than about 7.9 (e.g., high dielectric constant (high-k) material). For example, the dielectric layers 255a and 255b may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. In some embodiments, the dielectric layers 255a and 255b can be interchangeably referred to bottom dielectrics. In some embodiments, the dielectric layer 255a and/or 255b can have thickness T21/T22 in a range from about 3-40 nm, such as about 3, 5, 10, 15, 20, 25, 30, 35, or 40 nm.

In some embodiments, the dielectric layer 255a within the first circuit region 10A may have a lateral dimension D21 (see FIG. 10A) in parallel with the lengthwise direction of the semiconductor sheet 210, the dielectric layer 255b within the second circuit region 10B may have a lateral dimension D22 (see FIG. 10B) in parallel with the lengthwise direction of the semiconductor sheet 210, and the lateral dimension D22 may be greater than the lateral dimension D21.

Reference is made to FIGS. 11A and 11B. Eepitaxial source/drain regions 218a (see FIG. 11A) are formed in the source/drain recesses 94a, such that each dummy gate 84a (and corresponding channel regions) is disposed between respective adjacent pairs of the epitaxial source/drain regions 218a. Eepitaxial source/drain regions 218B (see FIG. 11B) are formed in the source/drain recesses 94b, such that each dummy gate 84b (and corresponding channel regions) is disposed between respective adjacent pairs of the epitaxial source/drain regions 218b. In some embodiments, the gate spacers 233a and the inner spacers 236a are used to separate the epitaxial source/drain regions 218a from, respectively, the dummy gate structures 84a and the first semiconductor sheets 310 by an appropriate lateral distance so that the epitaxial source/drain regions 218a do not short out with subsequently formed gates of the resulting nano-FETs. Similarly, the gate spacers 233b and the inner spacers 236b are used to separate the epitaxial source/drain regions 218b from, respectively, the dummy gate structures 84b and the first semiconductor sheets 310 by an appropriate lateral distance so that the epitaxial source/drain regions 218b do not short out with subsequently formed gates of the resulting nano-FETs. A material of the epitaxial source/drain regions 218a and 218b may be selected to exert stress in the respective channel regions, thereby improving performance of the semiconductor structure.

The epitaxial source/drain regions 218a and 218b in the first conductivity type device regions 10C and 10D (see FIG. 1) may be formed by masking the second conductivity type device regions 10E and 10F (see FIG. 1). Then, the epitaxial source/drain regions 218a and 218b in the first conductivity type device regions 10C and 10D can be epitaxially grown in the source/drain recesses 94a and 94b in the first conductivity type device regions 10C and 10D. The epitaxial source/drain regions 218a and 218b in the first conductivity type device regions 10C and 10D may include any acceptable material appropriate for n-type devices. For example, the epitaxial source/drain regions 218a and 218b in the first conductivity type device regions 10C and 10D may include materials exerting a tensile strain on the channel regions, such as silicon, silicon carbide, phosphorous doped silicon carbide, silicon phosphide, or the like. The epitaxial source/drain regions 218a and 218b in the first conductivity type device regions 10C and 10D may be referred to as “n-type source/drain region.” The epitaxial source/drain regions 218a and 218b in the first conductivity type device region 10C may have surfaces raised from respective surfaces of the fins 62 and the first and second semiconductor sheets 310, 210, and may have facets.

The epitaxial source/drain regions 218a and 218b in the second conductivity type device regions 10E and 10F (see FIG. 1) may be formed by masking the first conductivity type device regions 10C and 10D (see FIG. 1). Then, the epitaxial source/drain regions 218a and 218b in the second conductivity type device regions 10E and 10F can be epitaxially grown in the source/drain recesses 94a and 94b in the second conductivity type device regions 10E and 10F. The epitaxial source/drain regions 218a and 218b in the second conductivity type device regions 10E and 10F may include any acceptable material appropriate for p-type devices. For example, the epitaxial source/drain regions 218a and 218b in the second conductivity type device regions 10E and 10F may include materials exerting a compressive strain on the channel regions, such as silicon germanium, boron doped silicon germanium, germanium, germanium tin, or the like. The epitaxial source/drain regions 218a and 218b in the second conductivity type device regions 10E and 10F may be referred to as “p-type source/drain region.” In some embodiments, the source/drain regions 218a and 218b of the second conductivity type device regions 10E and 10F may have a boron concentration within a range from about 1E19/cm³ to about 6E20/cm³. In some embodiments, the source/drain regions 218a and 218b of the second conductivity type device regions 10E and 10F may have a Ge atomic percentage within a range of about 36% to about 85%. In some embodiments, the source/drain regions 218 can be interchangeably referred to source/drain patterns, epitaxial patterns, or epitaxial structures.

In some embodiments, the source/drain region 218a within the first circuit region 10A may have a lateral dimension D31 (see FIG. 11A) in parallel with the lengthwise direction of the semiconductor sheet 210, the source/drain regions 218b within the second circuit region 10B may have a lateral dimension D32 (see FIG. 11B) in parallel with the lengthwise direction of the semiconductor sheet 210, and the lateral dimension D32 may be greater than the lateral dimension D31.

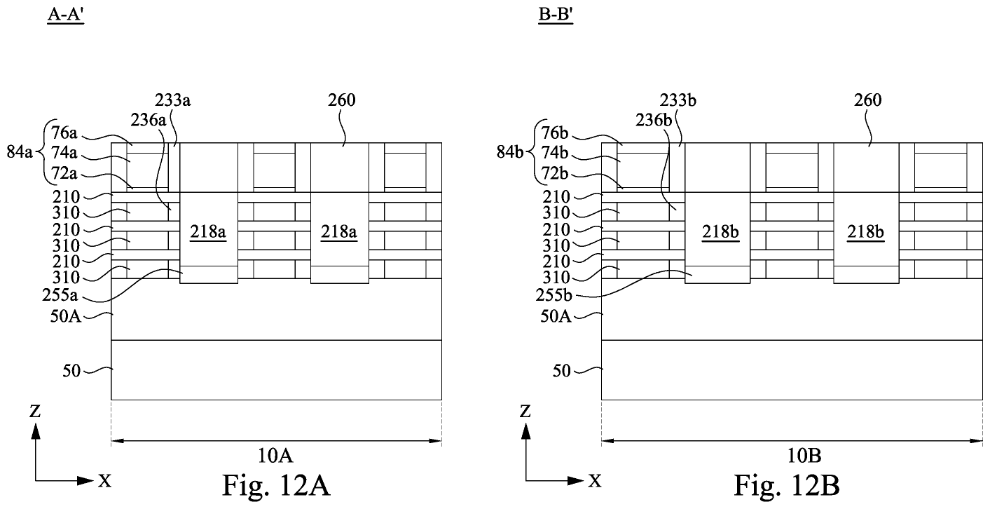

Reference is made to FIGS. 12A and 12B. An inter-layer dielectric (ILD) layer 260 is deposited over the epitaxial source/drain regions 218a and 218b, the gate spacers 233a and 233b, the dummy gate structures 84a and 84b within the first and second circuit regions 10A and 10B. The ILD layer 260 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) is formed between the ILD layer 260 and the epitaxial source/drain regions 218a and 218b, the gate spacers 233a and 233b, and the dummy gate structures 84a and 84b within the first and second circuit regions 10A and 10B. The CESL may be formed of a dielectric material, such as silicon nitride, silicon oxide, silicon oxynitride, or the like, having a high etching selectivity from the etching of the ILD 260. The CESL may be formed by an any suitable method, such as CVD, ALD, or the like.

Subsequently, a removal process is performed to level the top surfaces of the ILD layer 260 with the top surfaces of the dummy gate structures 84a and 84b. In some embodiments, a planarization process such as a chemical mechanical polish (CMP), an etch-back process, combinations thereof, or the like may be utilized. The planarization process may also remove the masks 76a and 76b on the dummy gate structures 84a and 84b, and portions of the gate spacers 233a and 233b along sidewalls of the masks 776a and 76b. After the planarization process, the top surfaces of the gate spacers 233a and 233b, the ILD layer 260, the CESL, and the dummy gate structures 84a and 84b are coplanar (within process variations). Accordingly, the top surfaces of the dummy gate structures 84a and 84b are exposed through the ILD layer 260. In some embodiments, the masks 76a and 76b remain, and the planarization process levels the top surfaces of the ILD layer 260 with the top surfaces of the masks 76a and 76b.

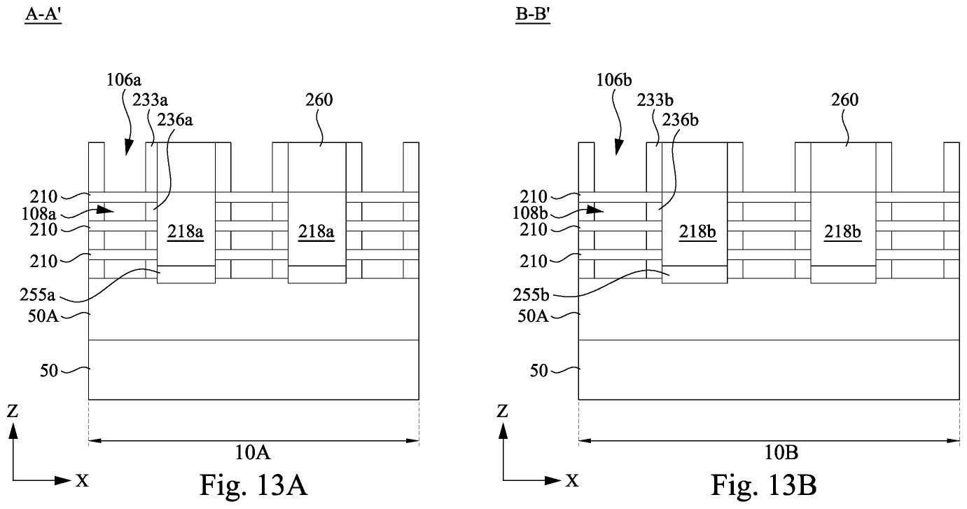

Reference is made to FIGS. 13A and 13B. The dummy gate structures 84a and 84b within the first and second circuit regions 10A and 10B are removed in an etching process, so that recesses 106a within the first circuit region 10A and recesses 106b within the first circuit region 10B are formed. Portions of the dummy dielectrics 72a in the recesses 106a are also removed, and portions of the dummy dielectrics 72b in the recesses 106b are also removed. In some embodiments, the dummy gate structures 84a and 84b are removed by an anisotropic dry etch process. For example, the etching process may include a dry etch process using reaction gas(es) that selectively etch the dummy gate structures 84a and 84b at a faster rate than the ILD layer 260 or the gate spacers 233a and 233b. During the removal, the dummy dielectrics 72a and 72b may be used as etch stop layers when the dummy gate structures 84a and 84b are etched. The dummy dielectrics 72a and 72b are then removed. Each recesses 106a and 106b exposes and/or overlies portions of the channel regions. Portions of the second semiconductor sheets 210 which act as the channel regions within the first and second circuit regions 10A and 10B are disposed between adjacent pairs of the epitaxial source/drain regions 218a and 218b.

The remaining portions of the first semiconductor sheets 310 within the first and second circuit regions 10A and 10B are then removed to expand the recesses 106a and 106b, such that openings 108a (see FIG. 13A) and openings 108b (see FIG. 13B) are formed in regions between the second semiconductor sheets 210. The remaining portions of the first semiconductor sheets 310 can be removed by any acceptable etching process that selectively etches the material of the first semiconductor sheets 310 at a faster rate than the material of the second semiconductor sheets 210. The etching may be isotropic. For example, when the first semiconductor sheets 310 are formed of silicon germanium and the second semiconductor sheets 210 are formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second semiconductor sheets 210. In some embodiments, the removing of the remaining portions of the first semiconductor sheets 310 can be interchangeably referred to as a channel releasing process. The second semiconductor sheets 210 can be interchangeably referred to as a vertically stacked multiple channels (sheets) and may have a vertically sheet pitch within a range of from about 10 nm to about 30 nm, such as about 10, 12, 14, 16, 18, 20, 22, 24, 26, 28, or 30 nm. The vertical sheet pitch P1 can be defined as the sum of a thickness of the sheet 210 (or channel) and a distance the between adjacent two of the second semiconductor sheets 210. In some embodiments, the second semiconductor sheets 210 may have a thickness within a range from about 4 nm to about 10 nm, such as about 4, 5, 6, 7, 8, 9, or 10 nm. In some embodiments, a distance the between adjacent two of the second semiconductor sheets 210 may be within a range from about 6 to about 20 nm, such as about 6, 8, 10, 12, 14, 16, 18, or 20 nm.

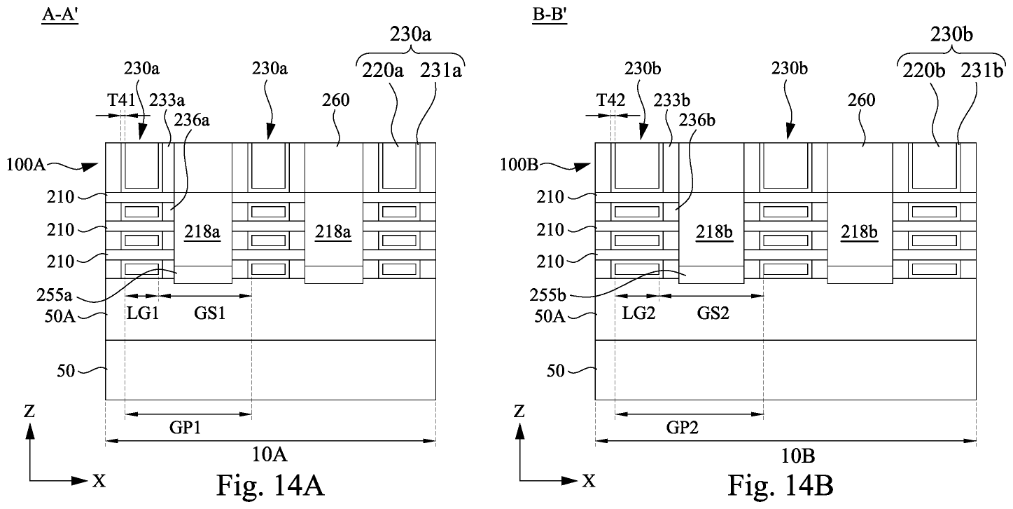

Reference is made to FIGS. 14A and 14B. Gate structures 230a are formed to wrap around the second semiconductor sheets 210 within the first circuit region 10A, and gate structures 230b are formed to wrap around the second semiconductor sheets 210 within the second circuit region 10B. Specifically, the gate structure 230a can include a gate dielectric layer 231a formed in the recesses 106a and a gate electrode layers 220a formed on the gate dielectric layer 231a. The gate dielectric layer 231a and the gate electrode layers 220a are layers for replacement gates of the resulting nano-FETs, and each wrap around all (e.g., four) sides of the second semiconductor sheet 210 within the first circuit region 10A. Similarly, the gate structure 230b can include a gate dielectric layer 231b formed in the recesses 106b and a gate electrode layers 220b formed on the gate dielectric layer 231b. The gate dielectric layer 231b and the gate electrode layers 220b are layers for replacement gates of the resulting nano-FETs, and each wrap around all (e.g., four) sides of the second semiconductor sheet 210 within the second circuit region 10B. In other words, the gate structures 230a and 203b each extend along top surfaces, sidewalls, and bottom surfaces of a channel region of the second semiconductor sheet 210. In some embodiments, the gate structure 230a and/or 230b can be interchangeably referred to as a gate, a gate layer, a gate strip, or a gate pattern. In some embodiments, the gate structure 230a and/or 230b can be interchangeable referred to as a functional gate, a metal gate, a gate pattern, a gate strip, or a gate layer.

The gate dielectric layer 231a/231b can be disposed on the sidewalls and/or the top surfaces of the fins 62; on the top surfaces, the sidewalls, and the bottom surfaces of the second semiconductor sheets 210; and on the sidewalls of the gate spacers 233a/233b. The gate dielectric layer 231a/231b may include an oxide such as silicon oxide or a metal oxide, a silicate such as a metal silicate, combinations thereof, multi-layers thereof, or the like. The gate dielectric layer 231a/231b may include a dielectric material having a k-value greater than about 7.0, such as a metal oxide or a silicate of hafnium, aluminum, zirconium, lanthanum, manganese, barium, titanium, lead, and combinations thereof. Although a single-layered gate dielectric layer 231a/231b is illustrated in FIGS. 14A and 14B, as will be subsequently described in greater detail, the gate dielectric layer 231a/231b may include any number of interfacial layers and any number of main layers. The formation of the gate dielectric layers 231a within the first circuit region 10A and the gate dielectric layers 231b within the second circuit region 10B may form simultaneously, such that the gate dielectric layers 231a and 231b in each region are formed of the same materials and the same thickness. By way of example but not limiting the present disclosure, the gate dielectric layers 231a may have a thickness D41 (see FIG. 14A), the gate dielectric layers 231b may have a thickness D42 (see FIG. 14B), and the thickness D42 can be the same as the thickness D41.

The gate electrode layers 220a/220b may include a metal-containing material such as titanium nitride, titanium oxide, tungsten, cobalt, ruthenium, aluminum, combinations thereof, multi-layers thereof, or the like. Although a single-layered gate electrode layers 220a/220b is illustrated in FIGS. 14A and 14B, as will be subsequently described in greater detail, the gate electrode layer 220a/220b may include any number of work function tuning layers, any number of barrier layers, any number of glue layers, and a fill material. In some embodiments, the gate electrode layers 220 may be made of a material selected from a group including TiN, TaN, TiAl, TiAIN, TaAl, TaAIN, TaAIC, TaCN, WNC, Co, Ni, Pt, W, or combinations thereof. The formation of the gate electrode layers 220a may form simultaneously such that the gate electrode layers 220b in each region are formed of the same materials. In some embodiments, the gate electrode layers 220a and 220b in each region may be formed by distinct processes, such that the gate electrode layers 220a and 220b in each region may be formed by distinct processes, such that the gate electrode layers 220a and 220b may be different materials and/or have a different number of layers. Various masking steps may be used to mask and expose appropriate regions when using distinct processes.

Subsequently, a removal process is performed to remove the excess portions of the materials of the gate dielectric layers 231a and 231b and the gate electrode layers 220a and 220b, which excess portions are over the top surfaces of the ILD layer 260 and the gate spacers 233a and 233b, thereby forming gate dielectric layer 231a and 231b and gate electrode layers 220a and 220b. In some embodiments, a planarization process such as a chemical mechanical polish (CMP), an etch-back process, combinations thereof, or the like may be utilized. The gate dielectric layer 231a and 231b, when planarized, has portions left in the recesses 106a and 106b (thus forming the gate dielectric layer 231a and 231b). The gate electrode layers 220a and 220b, when planarized, have portions left in the recesses 106a and 106b (thus forming the gate electrode layers 220a and 220b). The top surfaces of the gate spacers 233a and 233b; the CESL (not shown); the ILD layer 260; the gate dielectric layer 231a and 231b, and the gate electrode layers 220a and 220b are coplanar (within process variations).

By way of example but not limiting the present disclosure, the gate electrode layers 220a each have a gate length LG1 in a lengthwise direction of the semiconductor sheet 210, and the gate length LG1 can be in a range from about 8 nm to about 20 nm, such as about 8, 9, 10, 11, 12, 13, 14, 15, 16, 17, 18, 19, or 20 nm, and the gate electrode layers 220b each have a gate length LG2 in a lengthwise direction of the semiconductor sheet 210, and the gate length LG2 can be in a range from about 8 nm to about 16 nm, such as about 8, 9, 10, 11, 12, 13, 14, 15, or 16 nm. In some embodiments, the gate length LG2 of the gate electrode layer 220b can be greater than the gate length LG1 of the gate electrode layer 220a. By way of example but not limiting the present disclosure, a gate length ratio of gate length LG2 to gate length LG1 is within a range from about 1.1-3, such as about 1.1, 1.2, 1.4, 1.6, 1.8, 2, 2.2, 2.4, 2.6, or 2.8.

In some embodiments, the gate structures 230a within the first circuit region 10A have a gate space GS1, the gate structures 230b within the second circuit region 10B have a gate space GS2, and the gate space GS2 can be greater than the gate space GS1. By way of example but not limiting the present disclosure, a space ratio of the gate space GS2 to the gate space GS1 is within a range from about 1.1-2, such as about 1.1, 1.2, 1.3, 1.4, 1.5, 1.6, 1.7, 1.8, 1.9, or 2. In some embodiments, the gate structures 230a within the first circuit region 10A have a gate pitch GP1, and the gate structures 230b within the second circuit region 10B have a gate space GP2. The gate pitch dimension can be defined as the sum of the gate length (e.g., gate length LG1, gate length LG2) and the gate space (e.g., gate space GS1, gate space GS2). This means that the total distance from the start of one gate structure (e.g., gate structure 230a, gate structure 230b) to the start of the next adjacent gate structure (i.e., the gate pitch) is equal to the length of the gate itself (i.e., the gate length) plus the empty space between two consecutive gate structure (i.e., the gate space). In some embodiments, the gate space GP2 can be greater than the gate space GP1. By way of example but not limiting the present disclosure, a ratio of the gate pitch GP2 to the gate pitch GP1 is in a range from about 1.1-2, such as about 1.1, 1.2, 1.3, 1.4, 1.5, 1.6, 1.7, 1.8, 1.9, or 2. In some embodiments, the gate space GP1/GP2 can be interchangeably referred to a distance between adjacent two gate electrode layers (e.g., electrode layers 220a/electrode layers 220b).

In some embodiments, the transistor (semiconductor device) 100A can be formed within the first circuit region 10A (see FIG. 14A), and the transistor (semiconductor device) 100B can be formed within the first circuit region 10B (see FIG. 14B). The transistor 100A may include the channel layers 210, the source/drain regions 218a on opposite sides of the channel layers 210 and connected to the channel layers 210, and the gate structure 230a wrapping around the channel layers 210. The transistor 100B may include the channel layers 210, the source/drain regions 218b on opposite sides of the channel layers 210 and connected to the channel layers 210, and the gate structure 230b wrapping around the channel layers 210. In some embodiments, the transistor 100A can be of a core device, and the transistor 100B can be an non-core device. By way of example but not limiting the present disclosure, the transistor 100B can be of an e-fuse/analog circuits or a capacitor. In some embodiments, the transistor 100A can have individual source and drain nodes (e.g., source/drain region 218a), and the transistor 100B can have source and drain nodes (e.g., source/drain region 218b) being electrodes connected together. In some embodiments, the input/output (I/O) devices can be formed to have a thicker gate dielectric, in a range from about 5-30 Angstroms, compared to the transistors 100A and 100B. Additionally, these I/O devices can have a larger gate pitch, which could be expanded by a factor of about 1.4-5 times that of both the transistors 100A and 100B.

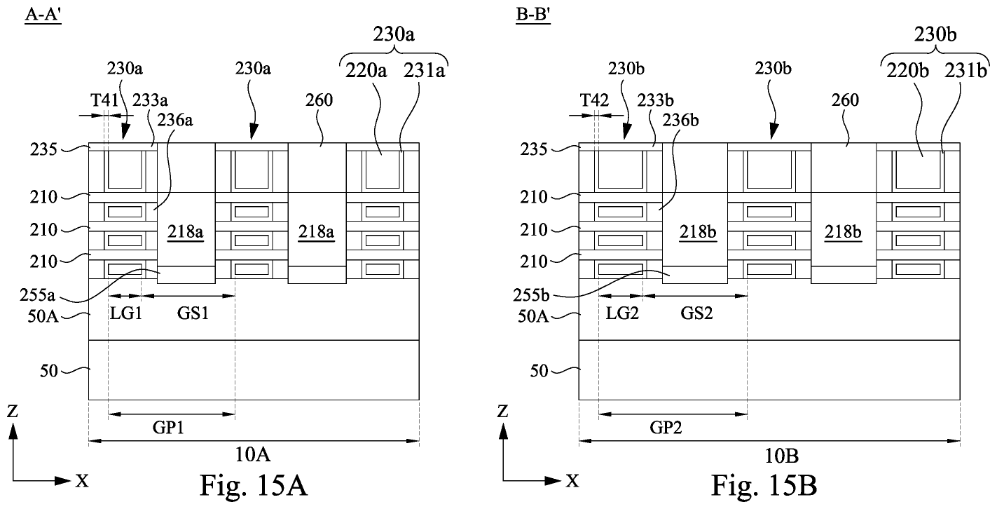

Reference is made to FIGS. 15A and 15B. An etch back process is performed on the gate electrode layers 220a and 220b, the gate dielectric layer 231a and 231b, and the gate spacers 233a and 233b to scale down the gate structures 230a and 230b and the gate spacers 233a and 233b. The etch back process may include a bias plasma etching step. The bias plasma etching step may be performed to remove portions of the gate electrode layers 220a and 220b, the gate dielectric layer 231a and 231b, and the gate spacers 233a and 233b. Portions of the gate trenches may reappear with shallower depth. Top surfaces of the gate electrode layers 220a and 220b, the gate dielectric layer 231a and 231b, and the gate spacers 233a and 233b may be no longer level with the ILD layer 260. In some embodiments, the bias plasma etching step may use a gas mixture of Cl₂, O₂, BCl₃, and Ar with a bias in a range from about 25V to about 1200V.

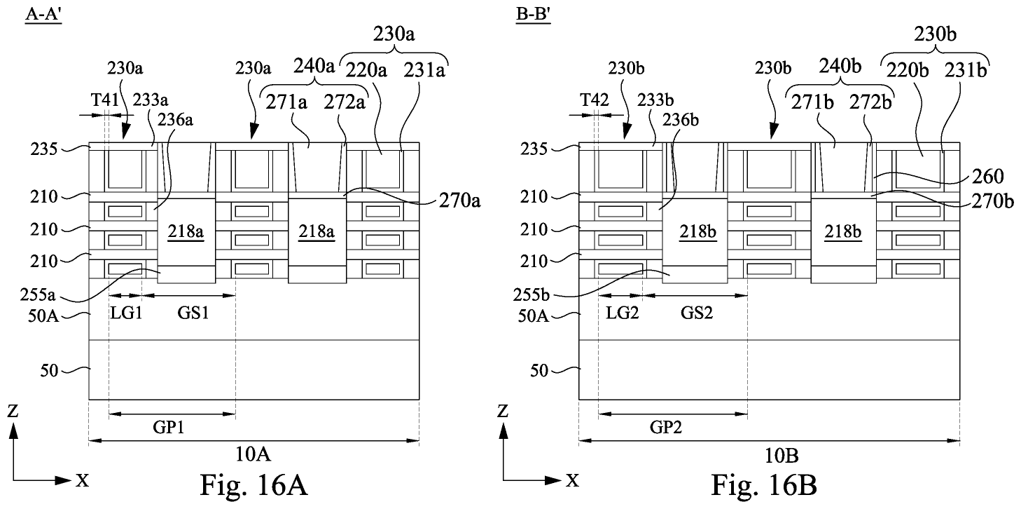

Subsequently, hard mask layers 235 can be formed over the gate structures 230a and 230b and the gate spacers 233a and 233b using, for example, a deposition process to deposit a dielectric material over the substrate 50, followed by a CMP process to remove excess dielectric material above the ILD layer 260. In some embodiments, source/drain contacts 240a and power supply voltage contacts 244a (see FIGS. 16A and 16B) formed subsequently are formed by a self-aligned contact process using the hard mask layers 235 as a contact etch protection layer. In some embodiments, the hard mask layer 235 may have a thickness in a range from about 2 nm to about 60 nm.

In some embodiments, the hard mask layer 235 may be made of a nitride-based material, such as Si₃N₄, SiON, or a carbon-based material, such as SiC, SiOC, SiOCN, or combinations thereof. In some embodiments, the hard mask layer 235 may include SiOₓ, SiBN, SiCBN, other suitable dielectric materials, or combinations thereof. In some embodiments, the hard mask layer 235 may include a metal oxide, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The hard mask layer 235 has different etch selectivity than the ILD layer 260, so as to selective etch back the hard mask layer 235. By way of example, if the hard mask layer 235 is made of silicon nitride, the ILD layer 260 may be made of a dielectric material different from silicon nitride. If the hard mask layer 235 is made of silicon carbide (SIC), the ILD layer 260 may be made of a dielectric material different from silicon carbide. Therefore, the hard mask layer 235 can be used to define self-aligned gate contact region and thus referred to as a self-aligned contact (SAC) structure or a SAC layer.

The dielectric regions 227 (see FIGS. 1, 2G, and 2H) are formed on opposite ends of the gate structures 230a and 230b. In some embodiments, each dielectric region 227 is a gate-cut structure for the gate structure, and the gate-cut structure is formed by a cut metal gate (CMG) process. In some embodiments, the dielectric region 227 can be interchangeably referred to a gate end dielectric. Specifically, the opposite ends the gate electrode layers 220a and 220b (and gate dielectric layers 231a and 231b) are removed to form gate trenches. The ends of the gate electrode layers 220a and 220b may be removed by dry etching, wet etching, or a combination of dry and wet etching. For example, a wet etching process may include exposure to a hydroxide containing solution (e.g., ammonium hydroxide), deionized water, and/or other suitable etchant solutions. Subsequently, a dielectric material is deposited into the gate trenches, followed by a planarization process to remove excess portions of the dielectric material. The remaining dielectric material forms the dielectric regions 227.

In some embodiments, the deposition of the dielectric material of the dielectric regions 227 (see FIGS. 1, 2G, and 2H) is performed using a conformal deposition process such as ALD, which may be PEALD, thermal ALD, or the like. The dielectric material may be formed of or comprise SiO₂, SiOC, SiOCN, or the like, or combinations thereof. In some embodiments, the dielectric region 227 may be made of a nitride-based material, such as Si₃N₄, or a carbon-based material, such as SiOCN, or combinations thereof. In some embodiments, the dielectric region 227 may be made of a material having a dielectric constant greater than about 9 (e.g., high dielectric constant (high-k) material). For example, the dielectric region 227 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric regions 227 may be formed of a homogenous material, or may have a composite structure including more than one layer. The dielectric regions 227 may include dielectric liners, which may be formed of, for example, silicon oxide. In some embodiments, the dielectric material of the dielectric regions 227 comprises SiN, and the deposition is performed using process gases including dichlorosilane and ammonia. Hydrogen (H₂) may or may not be added.

Reference is made to FIGS. 16A and 16B. In FIG. 16A, source/drain contacts 240a and power supply voltage contacts 244a are formed in the ILD layer 260 and on the source/drain regions 218a within the first circuit region 10A. The source/drain contacts 240a may include contact metal 271a and barrier layer 272a. The power supply voltage contacts 244a may include contact metal 281a and barrier layer 282a. As shown in FIG. 16A, the source/drain contacts 240a and power supply voltage contacts 244a can be in contact with the spacers 233a and the hard mask layer 235 surrounding the gate structures 230a, and thus the gate structures 230a can be interchangeable referred to as a self-aligned contact scheme. In some embodiments, the source/drain silicide regions 270a can be formed between the source/drain contacts 240a and the source/drain regions 218a and between the power supply voltage contacts 244a and the source/drain regions 218a.

In FIG. 16B, source/drain contacts 240b and power supply voltage contacts 244b are formed in the ILD layer 260 and on the source/drain regions 218b within the second circuit region 10B. The source/drain contacts 240b may include contact metal 271b and barrier layer 272b. The power supply voltage contacts 244b may include contact metal 281b and barrier layer 282b. As shown in FIG. 16B, the source/drain contacts 240b and power supply voltage contacts 244b can be spaced apart from the spacers 233b and the hard mask layer 235 by the ILD layer 260, the ILD layer 260 surrounds the gate structures 230b, and thus the gate structures 230b can be interchangeable referred to as a non-self-aligned contact scheme. In some embodiments, the source/drain silicide regions 270b can be formed between the source/drain contacts 240b and the source/drain regions 218b and between the power supply voltage contacts 244a and the source/drain regions 218b. In some embodiments, materials of the source/drain contacts 240a and 240b and the power supply voltage contacts 244a and 244b may include Cu, Co, Ru, Pt, Al, W, Ti, TaN, TiN, or any combinations thereof.

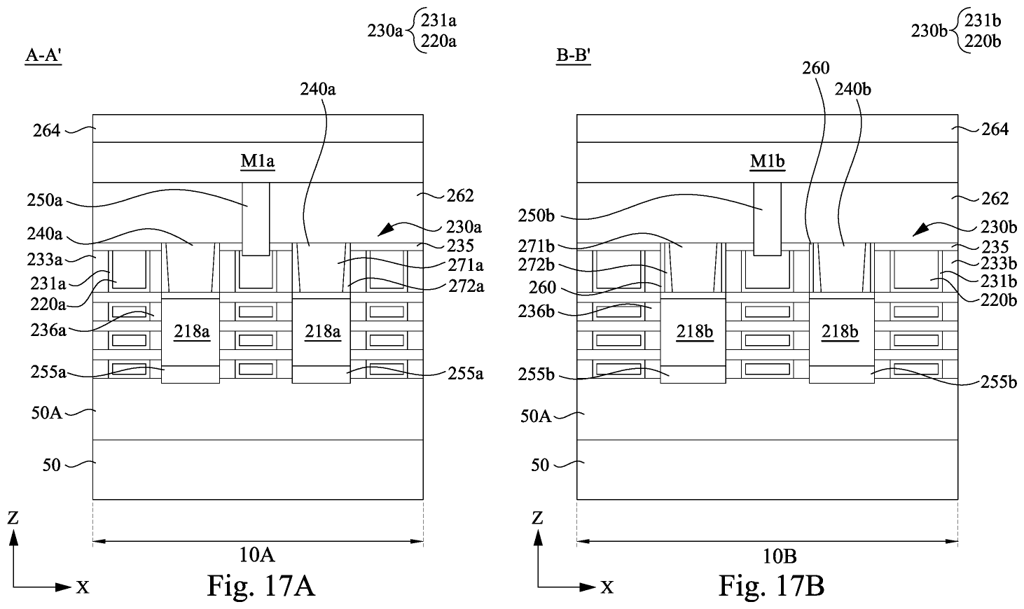

Reference is made to FIGS. 17A and 17B. Source/drain vias 242a and conductive vias 246a are formed in an ILD layer 262 over the ILD layer 260 within the first circuit region 10A, such that the source/drain vias 242a and the conductive vias 246a land on the source/drain contacts 240a and the power supply voltage contact 244a, respectively. Source/drain vias 242b and conductive vias 246b are formed in an ILD layer 262 over the ILD layer 260 within the second circuit region 10B, such that the source/drain vias 242b and the conductive vias 246b land on the source/drain contacts 240a and the power supply voltage contact 244a, respectively. In some embodiments, the conductive vias 246a and 246b can be interchangeably referred to source/drain vias. Gate vias 250a and 250b are formed to pass through the ILD layer 262 and the hard mask layer 235 and land on the gate electrode layers 220a and 220b. The source/drain vias 242a and 242b, the conductive vias 246a and 246b, and the gate vias 250a and 250b may include a metal-containing material such as titanium nitride, titanium oxide, tungsten, cobalt, ruthenium, aluminum, copper, combinations thereof, multi-layers thereof, or the like. The ILD layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Subsequently, an interconnect structure is formed over the gate vias 250a and 250b, the source/drain vias 242a and 242b, and the conductive vias 246. The interconnect structure includes a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The interconnect structure may include metal lines M1a and power supply voltage lines M1a-Vdd, M1a-Vss formed in a first front-side metallization layer within the first circuit region 10A. Also, the interconnect structure may include metal lines M1b and power supply voltage lines M1b-Vdd, M1b-Vss formed in a first front-side metallization layer within the second circuit region 10B.

The metal lines M1a, M1b, and the power supply voltage lines M1a-Vdd, M1a-Vss, M1b-Vdd, and M1b-Vss are in an IMD (inter-metal dielectric) layer 264. The metal layers M1a are electrically connected to the gate electrode layers 220a through the gate vias 250a, and electrically connected to the source/drain regions 218a through the source/drain vias 242a and the source/drain contacts 240a. The metal layers M1b are electrically connected to the gate electrode layers 220b through the gate vias 250b, and electrically connected to the source/drain regions 218b through the source/drain vias 242b and the source/drain contacts 240b. The power supply voltage lines M1a-Vdd, M1a-Vss are electrically connected to the source/drain regions 218a through the conductive vias 246a and the power supply voltage contact 244a. The power supply voltage lines M1b-Vdd, M1b-Vss are electrically connected to the source/drain regions 218b through the conductive vias 246b and the power supply voltage contact 244b. In some embodiments, materials of the metal lines M1a, M1b, and the power supply voltage lines M1a-Vdd, M1a-Vss, M1b-Vdd, and M1b-Vss may include Cu, Co, Ru, Pt, Al, W, Ti, TaN, TiN, or any combinations thereof. In some embodiments, the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a single chip integrating multiple device structures to achieve high density, high-speed, and high-voltage applications. Variations in gate pitches can serve distinct feature: a semiconductor device with its larger gate pitch, can employ a thicker inner spacer, reducing contact-to-gate capacitance; while another semiconductor device, with a smaller gate pitch, can employ a thinner inner spacer to preserve contact area and enhance density. For high-voltage devices, a thicker inner spacer can be utilized to improve the breakdown voltage between the gate and source/drain region. This design versatility grants designers greater latitude in optimizing chip density and performance.

In some embodiments, a method includes forming first semiconductive sheets over a substrate and arranged in a vertical direction, second semiconductive sheets over the substrate and arranged in the vertical direction, third semiconductive sheets over the substrate and arranged in the vertical direction, and fourth semiconductive sheets over the substrate and arranged in the vertical direction; forming a first source/drain region between the first semiconductive sheets and the second semiconductive sheets, and a second source/drain region between the third semiconductive sheets and the second semiconductive sheets; forming a first gate around each of the first semiconductive sheets, a second gate around each of the second semiconductive sheets, a third gate around each of the third semiconductive sheets, and a fourth gate around each of the fourth semiconductive sheets, wherein the first and second gates has a first gate pitch therebetween, the third and fourth gates has a second gate pitch therebetween, and the second gate pitch is greater than the first gate pitch; forming first spacers interleaving with the first semiconductive sheets and between the first gate and the first source/drain region, and second spacers interleaving with the third semiconductive sheets and between the third gate and the second source/drain region, wherein the first spacers each has a first lateral dimension in a lengthwise direction of one of the first semiconductive sheets, the second spacers each has a second lateral dimension in the lengthwise direction of the one of the first semiconductive sheets, and the second lateral dimension is greater than the first lateral dimension. In some embodiments, a gate pitch ratio of the second gate pitch to the first gate pitch is greater than about 1.1. In some embodiments, a ratio of the second lateral dimension of the second spacers to the first lateral dimension of the first spacers is greater than about 1.05. In some embodiments, the first, second, third, and fourth gates each comprises a gate dielectric layer and a gate electrode layer over the gate dielectric layer, and the gate dielectric layer of the first gate, the gate dielectric layer of the second gate, the gate dielectric layer of the third gate, the gate dielectric layer of the fourth gate have a same thickness as each other. In some embodiments, the gate electrode layer of the first gate and the gate electrode layer of the second gate have a first distance therebetween, the gate electrode layer of the third gate and the gate electrode layer of the fourth gate have a second distance therebetween, and the second distance is greater than the first distance. In some embodiments, a ratio of the second distance to the first distance is greater than about 1.1. In some embodiments, the gate electrode layer of the first gate has a first gate length, the gate electrode layer of the third gate has a second gate length, and the second gate length is longer than the first gate length. In some embodiments, a gate length ratio of the second gate length to the first gate length is greater than about 1.1. In some embodiments, the first gate length is in a range from about 8-20 nm, and the second gate length is in a range from about 8-16 nm. In some embodiments, the first and second semiconductive sheets, the first and second gates, and the first source/drain region are of a core device, and the third and fourth semiconductive sheets, the third and fourth gates, and the second source/drain region are of a device for a capacitor or being of an e-fuse or an analog circuit.

In some embodiments, a method includes forming a first device over a substrate, in which the first device is of a core device and includes a first channel pattern, a first gate pattern, first epitaxial patterns, and first inner spacer, the first gate pattern wraps around the first channel pattern, the first epitaxial patterns are on either side of the first channel pattern, and the first inner spacer is below the first channel pattern and laterally sandwiched between the first gate pattern and one of the first epitaxial patterns; forming a second device over the substrate, in which the second device is of an non-core device, and incudes a second channel pattern, a second gate pattern, second epitaxial patterns, and a second inner spacer, the second gate pattern wraps around the second channel pattern, the second epitaxial patterns are on either side of the second channel pattern, and the second inner spacer is below the second channel pattern and laterally sandwiched between the second gate pattern and one of the second epitaxial patterns. The first gate pattern has a first gate length, the second gate pattern has a second gate length, the second gate length is longer than the first gate length. The second inner spacer has a greater lateral dimension than the first inner spacer in a lengthwise direction of the first channel pattern. In some embodiments, the first device comprises a first top spacer over the first channel pattern and on a sidewall of the first gate pattern, the second device comprises a second top spacer over the first channel pattern and on a sidewall of the second gate pattern, and the second top spacer has a thicker thickness than the first top spacer. In some embodiments, the second top spacer is thicker than the first top spacer in a range from about 0.5 to 5 nm. In some embodiments, the method further includes forming a contact over one of the first epitaxial patterns, the contact being in contact with the first top spacer. In some embodiments, the method further includes forming a contact over one of the second epitaxial patterns, the contact being spaced apart from the second top spacer.

In some embodiments, the semiconductor structure includes a substrate, a first transistor, a first dielectric spacer, and second dielectric spacers. The first transistor is over a substrate and includes first nanostructures, first epitaxial structures, and a first gate structure. The first nanostructures are arranged in a vertical direction. The first epitaxial structures are on either side of each of the first nanostructures. The first gate structure arounds the first nanostructures and is between the first epitaxial structures. The first dielectric spacer is over the first nanostructures and on a sidewall of the first gate structure. The second dielectric spacers interleaves with the first nanostructures and are between the first gate structure and one of the first epitaxial structures. Each of the second dielectric spacers has a greater lateral dimension than the first dielectric spacer in a lengthwise direction of one of the first nanostructures. In some embodiments, the semiconductor structure further includes a second transistor and third dielectric spacers. The second transistor includes second nanostructures, second epitaxial structures, and a second gate structure. The second nanostructures are arranged in the vertical direction. The second epitaxial structures are on either side of each of the second nanostructures. The second gate structure is around the second nanostructures and between the second epitaxial structures. The third dielectric spacers interleaves with the second nanostructures and are between the second gate structure and one of the second epitaxial structures. Each of the second dielectric spacers has a greater lateral dimension than the third dielectric spacers in the lengthwise direction of the one of the first nanostructures. In some embodiments, the first transistor is of a core device, and the second transistor is of a device for a capacitor or being of an e-fuse or an analog circuit. In some embodiments, the first gate structure has a first gate length, the second gate structure has a second gate length, and the first gate length is longer than the second gate length. In some embodiments, the semiconductor structure further includes a dielectric layer between one of the first epitaxial structures and the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming first semiconductive sheets over a substrate and arranged in a vertical direction, second semiconductive sheets over the substrate and arranged in the vertical direction, third semiconductive sheets over the substrate and arranged in the vertical direction, and fourth semiconductive sheets over the substrate and arranged in the vertical direction;
forming a first source/drain region between the first semiconductive sheets and the second semiconductive sheets, and a second source/drain region between the third semiconductive sheets and the second semiconductive sheets;
forming a first gate around each of the first semiconductive sheets, a second gate around each of the second semiconductive sheets, a third gate around each of the third semiconductive sheets, and a fourth gate around each of the fourth semiconductive sheets,
wherein the first and second gates has a first gate pitch therebetween, the third and fourth gates has a second gate pitch therebetween, and the second gate pitch is greater than the first gate pitch; and
forming first spacers interleaving with the first semiconductive sheets and between the first gate and the first source/drain region, and second spacers interleaving with the third semiconductive sheets and between the third gate and the second source/drain region, wherein the first spacers each has a first lateral dimension in a lengthwise direction of one of the first semiconductive sheets, the second spacers each has a second lateral dimension in the lengthwise direction of the one of the first semiconductive sheets, and the second lateral dimension is greater than the first lateral dimension.

2. The method of claim 1, wherein a gate pitch ratio of the second gate pitch to the first gate pitch is greater than about 1.1.

3. The method of claim 1, wherein a ratio of the second lateral dimension of the second spacers to the first lateral dimension of the first spacers is greater than about 1.05.

4. The method of claim 1, wherein the first, second, third, and fourth gates each comprises a gate dielectric layer and a gate electrode layer over the gate dielectric layer, and the gate dielectric layer of the first gate, the gate dielectric layer of the second gate, the gate dielectric layer of the third gate, the gate dielectric layer of the fourth gate have a same thickness as each other.

5. The method of claim 4, wherein the gate electrode layer of the first gate and the gate electrode layer of the second gate have a first distance therebetween, the gate electrode layer of the third gate and the gate electrode layer of the fourth gate have a second distance therebetween, and the second distance is greater than the first distance.

6. The method of claim 5, wherein a ratio of the second distance to the first distance is greater than about 1.1.

7. The method of claim 5, wherein the gate electrode layer of the first gate has a first gate length, the gate electrode layer of the third gate has a second gate length, and the second gate length is longer than the first gate length.

8. The method of claim 7, wherein a gate length ratio of the second gate length to the first gate length is greater than about 1.1.

9. The method of claim 7, wherein the first gate length is in a range from about 8-20 nm, and the second gate length is in a range from about 8-16 nm.

10. The method of claim 1, wherein the first and second semiconductive sheets, the first and second gates, and the first source/drain region are of a core device, and the third and fourth semiconductive sheets, the third and fourth gates, and the second source/drain region are of a device for a capacitor or being of an e-fuse or an analog circuit.

11. A method, comprising:
forming a first device over a substrate, the first device being of a core device, and comprising:
a first channel pattern;
a first gate pattern wrapping around the first channel pattern;
first epitaxial patterns on either side of the first channel pattern; and
a first inner spacer below the first channel pattern and laterally sandwiched between the first gate pattern and one of the first epitaxial patterns; and
forming a second device over the substrate, the second device being of an non-core device, and comprising:
a second channel pattern;
a second gate pattern wrapping around the second channel pattern, wherein the first gate pattern has a first gate length, the second gate pattern has a second gate length, the second gate length is longer than the first gate length;
second epitaxial patterns on either side of the second channel pattern; and
a second inner spacer below the second channel pattern and laterally sandwiched between the second gate pattern and one of the second epitaxial patterns, wherein the second inner spacer has a greater lateral dimension than the first inner spacer in a lengthwise direction of the first channel pattern.

12. The method of claim 11, wherein the first device comprises a first top spacer over the first channel pattern and on a sidewall of the first gate pattern, the second device comprises a second top spacer over the first channel pattern and on a sidewall of the second gate pattern, and the second top spacer has a thicker thickness than the first top spacer.

13. The method of claim 12, wherein the second top spacer is thicker than the first top spacer in a range from about 0.5 to 5 nm.

14. The method of claim 12, further comprising:
forming a contact over one of the first epitaxial patterns, the contact being in contact with the first top spacer.

15. The method of claim 12, further comprising:
forming a contact over one of the second epitaxial patterns, the contact being spaced apart from the second top spacer.

16. A semiconductor structure, comprising:
a substrate;
a first transistor over a substrate, the first transistor comprising:
first nanostructures arranged in a vertical direction;
first epitaxial structures on either side of each of the first nanostructures; and
a first gate structure around the first nanostructures and between the first epitaxial structures;
a first dielectric spacer over the first nanostructures and on a sidewall of the first gate structure; and
second dielectric spacers interleaving with the first nanostructures and between the first gate structure and one of the first epitaxial structures, wherein each of the second dielectric spacers has a greater lateral dimension than the first dielectric spacer in a lengthwise direction of one of the first nanostructures.

17. The semiconductor structure of claim 16, further comprising:
a second transistor over the substrate, the first transistor comprising:
second nanostructures arranged in the vertical direction;
second epitaxial structures on either side of each of the second nanostructures; and
a second gate structure around the second nanostructures and between the second epitaxial structures; and
third dielectric spacers interleaving with the second nanostructures and between the second gate structure and one of the second epitaxial structures, wherein each of the second dielectric spacers has a greater lateral dimension than the third dielectric spacers in the lengthwise direction of the one of the first nanostructures.

18. The semiconductor structure of claim 17, wherein the first transistor is of a core device, and the second transistor is of a device for a capacitor or being of an e-fuse or an analog circuit.

19. The semiconductor structure of claim 17, wherein the first gate structure has a first gate length, the second gate structure has a second gate length, and the first gate length is longer than the second gate length.

20. The semiconductor structure of claim 16, further comprising:
a dielectric layer between one of the first epitaxial structures and the substrate.
